(19) United States
(12) Patent Application Publication
(10) Pub. No.: US 2025/0024741 A1
(43) Pub. Date: Jan. 16, 2025

(54) LIGHT-EMITTING APPARATUS, DISPLAY DEVICE, AND ELECTRONIC APPLIANCE

(71) Applicant: Semiconductor Energy Laboratory Co., Ltd., Atsugi-shi, Kanagawa-ken (JP)

(72) Inventors: Takeyoshi WATABE, Atsugi (JP); Nobuharu OHSAWA, Zama (JP); Satoshi SEO, Sagamihara (JP)

(21) Appl. No.: 18/710,336

(22) PCT Filed: Nov. 16, 2022
(86) PCT No.: PCT/IB2022/061006

§ 371 Date: May 15, 2024

(30) Foreign Application Priority Data
Nov. 26, 2021 (JP) 2021-191857

(51) Int. Cl. H10K 59/80; H10K 50/15; H10K 50/17; H10K 50/18

(52) U.S. Cl. CPC H10K 59/879; H10K 50/15; H10K 50/17; H10K 50/181

(57) ABSTRACT

A light-emitting apparatus with high emission efficiency is provided. A light-emitting apparatus including a light-emitting device A and a light-emitting device B is provided. The light-emitting device A includes a first electrode A, a second electrode A, a light-emitting layer A interposed between the first electrode A and the second electrode A, and a first layer A interposed between the first electrode A and the light-emitting layer A. The light-emitting device B includes a first electrode B, a second electrode B, a light-emitting layer B interposed between the first electrode B and the second electrode B, a first layer B interposed between the first electrode B and the light-emitting layer B, and a second layer B interposed between the first electrode B and the light-emitting layer B. The light-emitting layer A contains a light-emitting substance A. The light-emitting layer B contains a light-emitting substance B. An emission peak wavelength of the light-emitting substance A is shorter than an emission peak wavelength of the light-emitting substance B. The first layer A and the first layer B contain the same material. An ordinary refractive index of the second layer B is lower than an ordinary refractive index of the first layer A by a value 0.15 or more, with respect to the emission peak wavelength of the light-emitting substance B.

### TECHNICAL FIELD

One embodiment of the present invention relates to an organic compound, a light-emitting element, a light-emitting device, a display module, a lighting module, a display device, a light-emitting apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a semiconductor device, a display device, a liquid crystal display device, a light-emitting apparatus, a lighting device, a power storage device, a memory device, an imaging device, a driving method thereof, and a manufacturing method thereof.

### BACKGROUND ART

Light-emitting devices (organic EL devices) including organic compounds and utilizing electroluminescence (EL) have been put to more practical use. In the basic structure of such light-emitting devices, an organic compound layer containing a light-emitting substance (an EL layer) is held between a pair of electrodes. Carriers are injected by application of voltage to the device, and recombination energy of the carriers is used, whereby light emission can be obtained from the light-emitting substance.

Such light-emitting devices are of self-luminous type and thus have advantages over liquid crystal devices, such as high visibility and no need for a backlight when used for pixels of a display, and are particularly suitable for flat panel displays. Displays including such light-emitting devices are also highly advantageous in that they can be thin and lightweight. Another feature is an extremely fast response speed.

Since light-emitting layers of such light-emitting devices can be successively formed two-dimensionally, planar light emission can be obtained. This feature is difficult to realize with point light sources typified by incandescent lamps and LEDs or linear light sources typified by fluorescent lamps; thus, the light-emitting devices also have great potential as planar light sources, which can be used for lighting and the like.

Displays and lighting devices including light-emitting devices are suitable for a variety of electronic appliances as described above, and research and development of light-emitting devices have progressed for more favorable characteristics.

Low light extraction efficiency is often a problem in an organic EL device. In order to improve the light extraction efficiency, a structure including a layer formed using a low refractive index material in an EL layer has been proposed (see Patent Document 1, for example).

### REFERENCE

### Patent Document

[Patent Document 1] United States Patent Application Publication No. 2020/0176692

### SUMMARY OF THE INVENTION

### Problems to be Solved by the Invention

An object of one embodiment of the present invention is to provide a light-emitting apparatus with high emission efficiency. Another object of one embodiment of the present invention is to provide a light-emitting apparatus having a long lifetime. Another object of one embodiment of the present invention is to provide a display device and an electronic appliance each having low power consumption. Another object of one embodiment of the present invention is to provide a novel light-emitting apparatus.

It is only necessary that at least one of the above-described objects be achieved in the present invention.

### Means for Solving the Problems

One embodiment of the present invention is a light-emitting apparatus including a light-emitting device A and a light-emitting device B. The light-emitting device A includes a first electrode A, a second electrode A, a light-emitting layer A interposed between the first electrode A and the second electrode A, and a first layer A interposed between the first electrode A and the light-emitting layer A. The light-emitting device B includes a first electrode B, a second electrode B, a light-emitting layer B interposed between the first electrode B and the second electrode B, a first layer B interposed between the first electrode B and the light-emitting layer B, and a second layer B interposed between the first electrode B and the light-emitting layer B. The light-emitting layer A contains a light-emitting substance A. The light-emitting layer B contains a light-emitting substance B. An emission peak wavelength of the light-emitting substance A is shorter than an emission peak wavelength of the light-emitting substance B. The first layer A and the first layer B contain the same material. An ordinary refractive index of the second layer B is lower than an ordinary refractive index of the first layer A by a value greater than or equal to 0.15, with respect to the emission peak wavelength of the light-emitting substance B.

One embodiment of the present invention is a light-emitting apparatus including a light-emitting device A and a light-emitting device B. The light-emitting device A includes a first electrode A, a second electrode A, a light-emitting layer A interposed between the first electrode A and the second electrode A, and a first layer A interposed between the first electrode A and the light-emitting layer A. The light-emitting device B includes a first electrode B, a second electrode B, a light-emitting layer B interposed between the first electrode B and the second electrode B, a first layer B interposed between the first electrode B and the light-emitting layer B, and a second layer B interposed between the first electrode B and the light-emitting layer B. The light-emitting layer A contains a light-emitting substance A. The light-emitting layer B contains a light-emitting substance B. An emission peak wavelength of the light-emitting substance A is shorter than an emission peak wavelength of the light-emitting substance B. The first layer A and the first layer B are formed using the same material. An ordinary refractive index of the second layer B is lower than an ordinary refractive index of the first layer A by a value greater than or equal to 0.15, with respect to the emission peak wavelength of the light-emitting substance B.

One embodiment of the present invention is a light-emitting apparatus including a light-emitting device A and a light-emitting device B. The light-emitting device A includes a first electrode A, a second electrode A, a light-emitting layer A interposed between the first electrode A and the second electrode A, and a first layer A interposed between the first electrode A and the light-emitting layer A. The light-emitting device B includes a first electrode B, a second electrode B, a light-emitting layer B interposed between the first electrode B and the second electrode B, a first layer B interposed between the first electrode B and the light-emitting layer B, and a second layer B interposed between the first electrode B and the light-emitting layer B. The light-emitting layer A contains a light-emitting substance A. The light-emitting layer B contains a light-emitting substance B. An emission peak wavelength of the light-emitting substance A is shorter than an emission peak wavelength of the light-emitting substance B. The first layer A and the first layer B have structures similar to each other. An ordinary refractive index of the second layer B is lower than an ordinary refractive index of the first layer A by a value greater than or equal to 0.15, with respect to the emission peak wavelength of the light-emitting substance B.

Another embodiment of the present invention is a light-emitting apparatus having any of the above structures, in which the ordinary refractive index of the first layer A is higher than or equal to 1.90 with respect to the emission peak wavelength of the light-emitting substance A.

Another embodiment of the present invention is a light-emitting apparatus having any of the above structures, in which the ordinary refractive index of the second layer B is lower than or equal to 1.75 with respect to the emission peak wavelength of the light-emitting substance B.

Another embodiment of the present invention is a light-emitting apparatus having any of the above structures, in which the second layer B is positioned between the first layer B and the light-emitting layer B.

Another embodiment of the present invention is a light-emitting apparatus having any of the above structures, in which the second layer B is positioned between the first electrode B and the first layer B.

Another embodiment of the present invention is a light-emitting apparatus having any of the above structures, in which the second layer B contains a substance having an acceptor property.

Another embodiment of the present invention is a display device including any of the light-emitting apparatuses described above.

Another embodiment of the present invention is an electronic appliance including any of the light-emitting apparatuses described above and a sensor, an operation button, a speaker, or a microphone.

Note that the display device in this specification includes, in its category, an image display device that uses a light-emitting device. The light-emitting apparatus may also include a module in which a light-emitting device is provided with a connector such as an anisotropic conductive film or a TCP (Tape Carrier Package), a module in which a printed wiring board is provided at the end of a TCP, and a module in which an IC (integrated circuit) is directly mounted on a light-emitting device by a COG (Chip On Glass) method.

### Effect of the Invention

In one embodiment of the present invention, a light-emitting apparatus with high emission efficiency can be provided. In another embodiment of the present invention, a light-emitting apparatus having a long lifetime can be provided. In another embodiment of the present invention, any of an electronic appliance, a display device, and a light-emitting apparatus each having low power consumption can be provided. In another embodiment of the present invention, a novel light-emitting apparatus can be provided.

Note that the description of these effects does not preclude the existence of other effects. One embodiment of the present invention does not need to have all these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A and FIG. 1B are schematic views of light-emitting apparatuses.

FIG. 2 is a schematic view of a light-emitting apparatus.

FIG. 3A and FIG. 3B are schematic views of light-emitting apparatuses.

FIG. 4A and FIG. 4B are schematic views of light-emitting apparatuses.

FIG. 5 is a schematic view of a light-emitting apparatus.

FIG. 6A and FIG. 6B are a top view and a cross-sectional view of a light-emitting apparatus.

FIG. 7 is a cross-sectional view of a light-emitting apparatus.

FIG. 8A, FIG. 8B, FIG. 8C, and FIG. 8D are diagrams illustrating electronic appliances.

FIG. 9A, FIG. 9B, and FIG. 9C are diagrams illustrating electronic appliances.

FIG. 10 is a diagram illustrating an in-vehicle electronic appliance.

FIG. 11A and FIG. 11B are diagrams illustrating an electronic appliance.

FIG. 12A, FIG. 12B, and FIG. 12C are diagrams illustrating an electronic appliance.

FIG. 13 shows refractive indices of PCBBiF.

FIG. 14 shows emission spectra used for calculation.

FIG. 15 shows refractive indices of DBfBB1TP, 2mDBTBPDBq-II, NBPhen, DBT3P-II, and aN-PNPAnth.

FIG. 16 shows refractive indices of dchPAF.

FIG. 17 is a graph showing the luminance-current density characteristics of a light-emitting device 1 and a comparative light-emitting device 1.

FIG. 18 is a graph showing the luminance-voltage characteristics of the light-emitting device 1 and the comparative light-emitting device 1.

FIG. 19 is a graph showing the current efficiency-luminance characteristics of the light-emitting device 1 and the comparative light-emitting device 1.

FIG. 20 is a graph showing the current density-voltage characteristics of the light-emitting device 1 and the comparative light-emitting device 1.

FIG. 21 is a graph showing the external quantum efficiency-luminance characteristics of the light-emitting device 1 and the comparative light-emitting device 1.

FIG. 22 is a graph showing emission spectra of the light-emitting device 1 and the comparative light-emitting device 1.

### MODE FOR CARRYING OUT THE INVENTION

Embodiments of the present invention will be described in detail below with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the case where light is incident on a material having optical anisotropy, light with a plane of vibration parallel to the optical axis is referred to as extraordinary light (rays) and light with a plane of vibration perpendicular to the optical axis is referred to as ordinary light (rays); the refractive index of the material with respect to ordinary light might differ from that with respect to extraordinary light. In such a case, the ordinary refractive index and the extraordinary refractive index can be separately calculated by anisotropy analysis. Note that in the case where the measured material has both the ordinary refractive index and the extraordinary refractive index, the ordinary refractive index is used as an index in this specification.

### Embodiment 1

In the case where a light-emitting device is used as a display element in a display to perform full-color display, a plurality of subpixels exhibiting different emission colors need to be provided in one pixel. Among some methods for forming a display performing full-color display, a separate coloring method provides a display in which subpixels with different emission colors include light-emitting devices that contain light-emitting substances exhibiting different emission peak wavelengths. For example, in the case where one pixel includes three subpixels, light-emitting devices included in the subpixels preferably contain a light-emitting substance having an emission peak wavelength in a red region, a light-emitting substance having an emission peak in a green region, and a light-emitting substance having an emission peak wavelength in a blue region.

Here, an improvement in light extraction efficiency of a light-emitting device can be expected by adjusting the thickness of the layer between the reflective electrode and the light-emitting layer in the light-emitting device in accordance with the emission color.

When the layer between the reflective electrode and the light-emitting layer, whose thickness is adjusted to improve light extraction efficiency of a light-emitting device exhibiting one emission color, is applied as it is, to a light-emitting device exhibiting another emission color, the light extraction efficiency might be decreased rather than improved effectively. Thus, the layer between the reflective electrode and the light-emitting layer generally needs to be formed independently so as to have a thickness suitable for each emission color. However, separately forming the layers suitable for respective emission colors requires repetition of steps in accordance with the number of stacked layers for each emission color, which is complicated, time consuming, and costly.

In view of the above, the structure of the light-emitting apparatus of one embodiment of the present invention is as follows: a layer between a reflective electrode and a light-emitting layer, which has an adjusted optical distance applicable to a light-emitting device included in a subpixel exhibiting an emission color with the shortest wavelength among a plurality of subpixels included in a pixel, is used in common with light-emitting devices exhibiting other emission colors. Note that the light-emitting devices exhibiting other emission colors each have a structure in which an optical adjustment layer with a low refractive index is further provided in the layer.

In the light-emitting apparatus of one embodiment of the present invention with the above structure, while the layer between the reflective electrode and the light-emitting layer is shared by light-emitting devices emitting a plurality of emission colors, a decrease in light extraction efficiency can be inhibited, and furthermore, the extraction efficiency of the light-emitting devices emitting a plurality of emission colors can be improved. In addition, the layer can be formed in the light-emitting devices in the same process by being shared by the light-emitting devices emitting a plurality of emission colors; thus, a light-emitting apparatus that has high emission efficiency and improved extraction efficiency of the light-emitting devices emitting a plurality of emission colors can be provided easily, promptly, and inexpensively.

Note that in one embodiment of the present invention, a light-emitting device exhibiting an emission color with a longer wavelength includes layers as they are, which are adjusted to be applicable to a light-emitting device exhibiting an emission color with a short wavelength, except for an optical adjustment layer with a low refractive index. Nonetheless, a decrease in efficiency is not caused, and instead, the efficiency improvement effect can be obtained, which is a significant feature of one embodiment of the present invention. When a layer between the reflective electrode and the light-emitting layer as it is, which is adjusted to be applicable to a light-emitting device exhibiting an emission color with a short wavelength, is used for a light-emitting device exhibiting an emission color with a long wavelength, the emission efficiency considerably decreases. Only a single optical adjustment layer with a low refractive index can eliminate the adverse effect and further produce an efficiency improvement effect, which is a significant effect that cannot normally be assumed.

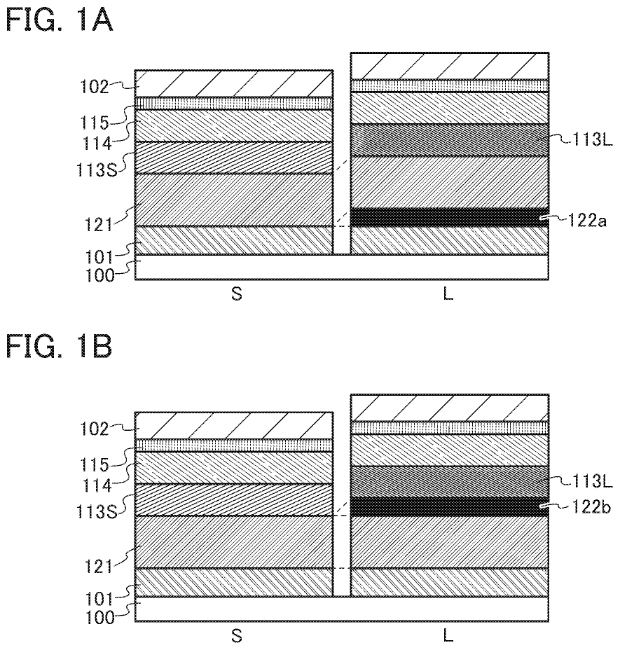

FIG. 1A and FIG. 1B are diagrams each illustrating a light-emitting apparatus of one embodiment of the present invention. In FIG. 1A and FIG. 1B, two light-emitting devices exhibiting different emission colors in the light-emitting apparatus are selectively illustrated.

The light-emitting apparatus illustrated in FIG. 1A and FIG. 1B includes a light-emitting device S and a light-emitting device L over an insulating layer 100. The light-emitting device L illustrated in the right side is a light-emitting device that exhibits an emission color with a longer wavelength than that of the light-emitting device S.

The light-emitting device S includes at least a first electrode 101, a first layer 121, a light-emitting layer 113S, and a second electrode 102 over the insulating layer 100. The light-emitting layer 113S is interposed between the first electrode 101 and the second electrode 102. The first layer 121 is interposed between the first electrode 101 and the light-emitting layer 113S. Note that the light-emitting layer 113S contains a light-emitting substance S.

The light-emitting device L includes at least the first electrode 101, the first layer 121, a second layer 122, a light-emitting layer 113L, and the second electrode 102 over the insulating layer 100. The light-emitting layer 113L is interposed between the first electrode 101 and the second electrode 102. The first layer 121 and the second layer 122 are interposed between the first electrode 101 and the light-emitting layer 113L. Note that the light-emitting layer 113L contains a light-emitting substance L. The light-emitting substance L is a light-emitting substance whose emission peak wavelength is longer than that of the light-emitting substance S. As described later, the second layer 122 is an optical adjustment layer with a low refractive index.

The second layer 122 may be provided between the first electrode 101 and the first layer 121 as illustrated in FIG. 1A (a second layer 122a) or may be provided between the first layer 121 and the light-emitting layer 113L as illustrated in FIG. 1B (a second layer 122b).

Note that in this specification, the second layer 122a and the second layer 122b are collectively referred to as the second layer 122 in some cases.

With respect to light having a certain wavelength λ, the ordinary refractive index of the second layer 122 is preferably lower than the ordinary refractive index of the first layer 121, further preferably lower than the ordinary refractive index of the first layer 121 by a value 0.15 or more, still further preferably lower than the ordinary refractive index of the first layer 121 by a value 0.20 or more. The wavelength λ is one or all of the wavelengths higher than or equal to 450 nm and lower than or equal to 650 nm.

With respect to light having a certain wavelength λ, the ordinary refractive index of the second layer 122 is preferably lower than the ordinary refractive index of the light-emitting layer 113L, further preferably lower than the ordinary refractive index of the light-emitting layer 113L by a value 0.15 or more, still further preferably lower than the ordinary refractive index of the light-emitting layer 113L by a value 0.20 or more. The wavelength λ is one or all of the wavelengths higher than or equal to 450 nm and lower than or equal to 650 nm.

In the case where the light-emitting device L emits light in a green region, the wavelength λ is preferably one or all of the wavelengths higher than or equal to 520 nm and lower than or equal to 540 nm; and in the case where the light-emitting device L emits light in a red region, the wavelength λ is preferably one or all of the wavelengths of 610 nm to 640 nm. The wavelength λ is preferably an emission peak wavelength XL of the light-emitting substance L.

The ordinary refractive index of the first layer 121 with respect to light having the wavelength λ is preferably higher than or equal to 1.90 and lower than or equal to 2.30.

More specifically, in the case where the light-emitting device S emits light in a blue region, the ordinary refractive index of the first layer 121 at one or all of the wavelengths higher than or equal to 455 nm and lower than or equal to 465 nm, preferably at an emission peak wavelength λ_{S} of the light-emitting substance S is preferably higher than or equal to 1.75 and lower than or equal to 2.30, further preferably higher than or equal to 1.90 and lower than or equal to 2.30. In the case where the light-emitting device S emits light in a green region, the ordinary refractive index of the first layer 121 at one or all of the wavelengths higher than or equal to 520 nm and lower than or equal to 540 nm, preferably at the emission peak wavelength λ_{S} of the light-emitting substance S is preferably higher than or equal to 1.75 and lower than or equal to 2.30, further preferably higher than or equal to 1.80 and lower than or equal to 2.30. In the case where the light-emitting device S emits light in a red region, the ordinary refractive index of the first layer 121 at one or all of the wavelengths higher than or equal to 610 nm and lower than or equal to 640 nm, preferably at the emission peak wavelength λ_{S} of the light-emitting substance S is preferably higher than or equal to 1.75 and lower than or equal to 2.30, further preferably higher than or equal to 1.80 and lower than or equal to 2.30. Alternatively, the ordinary refractive index of the first layer 121 with respect to light having a wavelength of 633 nm is preferably higher than or equal to 1.75 and lower than or equal to 2.30, further preferably higher than or equal to 1.80 and lower than or equal to 2.30.

The ordinary refractive index of the second layer 122 with respect to light having the wavelength λ is preferably higher than or equal to 1.40 and lower than or equal to 1.75.

More specifically, in the case where the light-emitting device L emits light in a green region, the ordinary refractive index of the second layer 122 at one or all of the wavelengths higher than or equal to 520 nm and lower than or equal to 540 nm, preferably at the emission peak wavelength XL of the light-emitting substance L is preferably higher than or equal to 1.40 and lower than or equal to 1.75. In the case where the light-emitting device L emits light in a red region, the ordinary refractive index at one or all of the wavelengths higher than or equal to 610 nm and lower than or equal to 640 nm, preferably at the emission peak wavelength XL of the light-emitting substance L is preferably higher than or equal to 1.40 and lower than or equal to 1.75. Alternatively, the ordinary refractive index of the second layer 122 with respect to light having a wavelength of 633 nm is preferably higher than or equal to 1.40 and lower than or equal to 1.70.

The first layer 121 is provided between the first electrode 101 and the light-emitting layer 113S, and the second layer 122 is provided between the first electrode 101 and the light-emitting layer 113S and between the first electrode 101 and the light-emitting layer 113L. Since it is preferable that the first electrode 101 have a stacked-layer structure and the stacked-structure include an anode, the first layer 121 and the second layer 122 are each preferably a layer having a hole-transport property. Examples of the layer having a hole-transport property include a hole-injection layer, a hole-transport layer, and an electron-blocking layer. The first layer 121 and the second layer 122 may have a function of another functional layer having a hole-transport property. Between the first layer 121 and the second layer 122, a layer positioned on the first electrode 101 side can be a hole-injection layer, a layer positioned on the light-emitting layer 113S and the light-emitting layer 113L side can be an electron-blocking layer, and a layer positioned therebetween can be a hole-transport layer.

The first layer 121 and the second layer 122 may each be formed by stacking a plurality of layers stacked. For example, in the case where the hole-injection layer and the hole-transport layer have almost the same ordinary refractive index (e.g., in the case where the hole-injection layer and the hole-transport layer contain the same organic compound and only the hole-injection layer further contains an electron-acceptor material; specifically, the ordinary refractive index difference is within 0.05), the two layers can be collectively regarded as the first layer 121.

In the case where the second layer 122 is positioned between the first electrode 101 and the first layer 121 as illustrated in FIG. 1A, that is, in the case where the second layer 122a is used as a hole-injection layer, the hole-injection layers of the light-emitting device L and the light-emitting device S are independent of each other, so that crosstalk between adjacent light-emitting devices can be inhibited even in a high-resolution display device; thus, this structure is preferable. As described later, the hole-injection layer may be formed using a substance having an electron-acceptor property. That is, in the case where the second layer 122a is used as the hole-injection layer, the second layer 122a sometimes contains a substance having an electron-acceptor property.

The first electrode 101 is an electrode including a reflective electrode, and the second electrode 102 is an electrode having a property of transmitting visible light. Note that the first electrode 101 preferably includes an anode, and the second electrode 102 is preferably a cathode. In the case where the first electrode 101 has a stacked-layer structure, the electrode closest to the second electrode 102 side is preferably an electrode having a property of transmitting visible light and is preferably an anode. That is, the first electrode 101 preferably has a structure in which a light-transmitting electrode functioning as an anode is stacked over the reflective electrode. The second electrode 102 preferably has both a property of transmitting visible light and a function of reflecting visible light.

Specifically, the first electrode 101 preferably includes a reflective electrode having a visible light reflectivity of 40% or more, preferably 70% or more. The second electrode 102 is preferably a transflective electrode having a visible light reflectivity of 20% or more and 80% or less, preferably 40% or more and 70% or less. Each of the light-emitting device S and the light-emitting device L with such a structure can be a top-emission light-emitting device that emits light from the second electrode 102 side, and also be a light-emitting device having a microcavity structure when the thicknesses of the first layer 121 and the second layer 122 are adjusted.

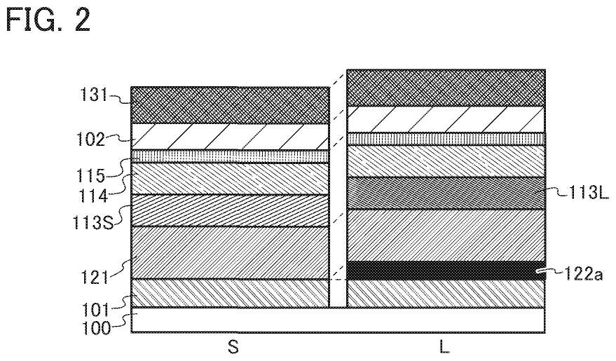

Note that a cap layer 131 (see FIG. 2) may be provided on a surface of the electrode through which light is emitted (the second electrode 102 in this embodiment), which is opposite to the light-emitting layer. The cap layer 131 is preferably formed using a material having a relatively high refractive index.

Specifically, the ordinary refractive index of the cap layer 131 at one of the wavelengths higher than or equal to 455 nm and lower than or equal to 465 nm, preferably in the entire wavelength range, is preferably higher than or equal to 1.90 and lower than or equal to 2.40, further preferably higher than or equal to 1.95 and lower than or equal to 2.40. Furthermore, the ordinary extinction coefficient of the cap layer at one of the wavelengths higher than or equal to 455 nm and lower than or equal to 465 nm, preferably in the entire wavelength range, is preferably higher than or equal to 0 and lower than or equal to 0.01. Alternatively, the ordinary refractive index of the cap layer 131 at one of the wavelengths higher than or equal to 500 nm and lower than or equal to 650 nm, preferably in the entire wavelength range, is preferably higher than or equal to 1.85 and lower than or equal to 2.40, further preferably higher than or equal to 1.90 and lower than or equal to 2.40. Furthermore, the ordinary extinction coefficient of the cap layer at one of the wavelengths higher than or equal to 500 nm and lower than or equal to 650 nm, preferably in the entire wavelength range, is preferably higher than or equal to 0 and lower than or equal to 0.01.

An organic compound that can be formed by evaporation is preferably used because the formation is easy. When the cap layer 131 is provided, light extraction efficiency can be improved to further increase emission efficiency. As a material for the cap layer 131, the following materials can be suitably used in addition to the organic compound given as a material capable of being used for the first layer 121: 3-{4-(triphenylen-2-yl)phenyl}-9-(triphenylen-2-yl)-9H-carbazole (abbreviation: TpPCzTp), 3,6-bis[4-(2-naphthyl)phenyl]-9-(2-naphthyl)-9H-carbazole (abbreviation: βNP2βNC), 9-[4-(2,2′-binaphthalen-6-yl)phenyl]-3-[4-(2-naphthyl)phenyl]-9H-carbazole (abbreviation: (βN2)PCPβN), 2-{4-[2-(N-phenyl-9H-carbazol-3-yl)-9H-carbazol-9-yl]phenyl}dibenzo[f,h]quinoxaline (abbreviation: 2PCCzPDBq-02), 9-[4-(9′-phenyl-3,3′-bi-9H-carbazol-9-yl)phenyl]naphtho[1′,2′:4,5]furo[2,3-b]pyrazine (abbreviation: 9pPCCzPNfpr), 4,8-bis[3-(triphenylen-2-yl)phenyl]-[1]benzofuro[3,2-d]pyrimidine (abbreviation: 4,8mTpP2Bfpm), and the like.

Here, the first layer 121 preferably has a thickness that allows light emitted from the light-emitting layer 113S and light reflected by the electrode in the light-emitting device S to be amplified by interference. The thickness of the second layer 122 is preferably a thickness that allows light emitted from the light-emitting layer 113L, light reflected by the electrode, and light reflected by the interface between the first layer 121 and the second layer 122 in the light-emitting device L to be amplified by interference.

When the first layer 121 is adjusted so that the optical path length of light emitted from the light-emitting layer 113S to a surface, which is on the second electrode 102 side, of the reflective electrode included in the first electrode 101 is 3λₜ/4, whereby the phases of reflected light at the surface and reflected light at the rear surface can be aligned with each other. Note that when the optical path length of light emitted from the light-emitting layer 113S to the surface, which is on the second electrode 102 side, of the reflective electrode included in the first electrode 101 is greater than or equal to 60% and less than or equal to 140% of 3λₜ/4, light interference can be effectively increased. Note that in the case where the first electrode 101 includes a light-transmitting electrode, the thickness of the light-transmitting electrode is preferably greater than or equal to 5 nm and less than or equal to 40 nm. In the case of using metal such as silver for the reflective electrode included in the first electrode 101, phase change sometimes shifts from 1800 when light is reflected by the reflective electrode. Accordingly, the optical path length of light emitted from the light-emitting layer 113S to the surface, which is on the second electrode 102 side, of the reflective electrode included in the first electrode 101 is sometimes shortened.

Note that the optical path length in this specification and the like is the product of the geometric length (nm) light travels and the refractive index of the medium through which the light propagates.

Note that in an actual light-emitting apparatus, λₜ corresponds to an emission peak wavelength λ_{SD} of light emitted from a subpixel including the light-emitting device S or the emission peak wavelength λ_{S} of the light-emitting substance S.

From the above, the product of the thickness (nm) and the ordinary refractive index of the first layer 121 at the wavelength λₜ (the wavelength λ_{SD} of light emitted from a subpixel including the light-emitting device S or the emission peak wavelength λ_{S} of the light-emitting substance S) is preferably greater than or equal to 0.25λₜ and less than or equal to 0.75λₜ.

A hole-injection layer having an ordinary refractive index of 1.75 or higher may be provided between the first layer 121 and the first electrode 101. In that case, the thickness of the hole-injection layer is preferably greater than or equal to 5 nm and less than or equal to 15 nm, further preferably greater than or equal to 5 nm and less than or equal to 10 nm, which can reduce the influence on the optical path length.

An electron-blocking layer may be provided between the first layer 121 and each of the light-emitting layer 113S and the light-emitting layer 113L. In that case, the thickness of the electron-blocking layer is preferably less than or equal to 20 nm, which can reduce the influence on the optical path length, and further preferably greater than or equal to 5 nm and less than or equal to 20 nm. It is further preferable that the thickness of the electron-blocking layer be regarded as part of the thickness of the light-emitting layer when the thickness of the first layer 121 is determined.

In the case where the hole-injection layer or the electron-blocking layer is formed, the hole-injection layer or the electron-blocking layer is preferably formed as a continuous layer shared by a plurality of light-emitting devices.

The optical distance between the interface of the reflective electrode on the first layer 121 side and the interface of the first layer 121 (or the second layer 122a) on the reflective electrode side is preferably greater than or equal to 0.13λₜ and less than or equal to 0.38λₜ. The optical path length between the main light-emitting region of the light-emitting layer 113S or the light-emitting layer 113L and the interface of the first layer 121 (or the second layer 122a) on the reflective electrode side is preferably greater than or equal to 0.38λₜ and less than or equal to 0.63λₜ. Such a structure enables light reflected by the interface of each layer and the reflective electrode to be amplified, so that a light-emitting device with high efficiency and high color purity can be obtained.

In the case where the second layer 122 (the second layer 122a) is provided between the first electrode 101 and the first layer 121 as illustrated in FIG. 1A, the optical path length from the main light-emitting region of the light-emitting layer 113L to an interface between the first layer 121 and the second layer 122 is adjusted to λₜ/2, whereby the phase of reflected light caused by the refractive index difference at the interface between the first layer 121 and the second layer 122 and the phase of light emitted from the light-emitting layer 113L can be aligned with each other. This effect presumably increases the light extraction efficiency. Note that when the optical path length from the main light-emitting region of the light-emitting layer 113L to an interface between the first layer 121 and the second layer 122 is greater than or equal to 60% and less than or equal to 140% of λₜ/2, light interference can be effectively increased.

In the case where the second layer 122 (the second layer 122b) is provided between the first layer 121 and the light-emitting layer 113L as illustrated in FIG. 1B, the optical path length from the main light-emitting region of the light-emitting layer 113L to an interface between the first layer 121 and the second layer 122 is adjusted to λₜ/4, whereby the phase of reflected light caused by the refractive index difference at the interface between the first layer 121 and the second layer 122 and the phase of light emitted from the light-emitting layer 113L can be aligned with each other. This effect presumably increases the light extraction efficiency. Note that when the optical path length from the main light-emitting region of the light-emitting layer 113L to an interface between the first layer 121 and the second layer 122 is greater than or equal to 60% and less than or equal to 140% of λₜ/4, light interference can be effectively increased.

It is preferable that the first layer 121 in the light-emitting device L and the first layer 121 in the light-emitting device S contain the same material and be formed using the same material.

The thickness of the first layer 121 in the light-emitting device L is similar to that of the first layer 121 in the light-emitting device S.

The composition and thickness of the first layer 121 in the light-emitting device L are preferably similar to those of the first layer 121 in the light-emitting device S.

Note that in this specification, the term “similar” may include a difference slight enough to allow fluctuations in composition and thickness accuracy of a deposition apparatus. Such a structure enables the first layer 121 in the light-emitting device L to be formed at the same time as the first layer 121 in the light-emitting device S. The first layer 121 has a thickness that allows light from the light-emitting device S to be amplified. This might reduce the extraction efficiency of the light-emitting device L; however, in one embodiment of the present invention, the light-emitting device L further includes the second layer 122 to improve the extraction efficiency, so that a light-emitting device efficiently emitting light can be achieved. Thus, in one embodiment of the present invention, a light-emitting apparatus including light-emitting devices with high emission efficiency of all emission colors can be obtained easily, promptly, and inexpensively.

In the case where any of the first layer 121 and the second layer 122 has a material and a composition similar to those of an adjacent layer, the boundary with the adjacent layer might be unclear so that the layers seem to be one layer. However, in such a case, the position and thickness of the second layer 122 can be estimated since a layer similar to the first layer 121 in the light-emitting device S is formed in the light-emitting device L.

The thicknesses of these layers may be determined with use of a commercially available organic device simulator.

The emission peak wavelength of a light-emitting substance is obtained from a photoluminescence spectrum in a solution state. Since the dielectric constant of an organic compound contained in an EL layer of a light-emitting device is approximately 3, in order to reduce the inconsistency with the emission spectrum of the organic compound used in the light-emitting device as much as possible, the dielectric constant of a solvent for bringing the light-emitting substance into a solution state is preferably greater than or equal to 1 and less than or equal to 10, further preferably greater than or equal to 2 and less than or equal to 5 at room temperature. Specific examples include hexane, benzene, toluene, diethyl ether, ethyl acetate, chloroform, chlorobenzene, and dichloromethane. A solvent that has a dielectric constant greater than or equal to 2 and less than or equal to 5 at room temperature, has high solubility, and is versatile is further preferable; for example, toluene or chloroform is preferably used.

The refractive index (the ordinary refractive index and the extraordinary refractive index) of a material contained in each layer can be regarded as the refractive index of the layer. For example, the refractive index of a film having a material composition similar to that included in the layer is measured, and the measured value can be regarded as the refractive index of the layer. Furthermore, as the highest occupied molecular orbital (HOMO) level of each layer, the HOMO level of a material contained in the highest proportion in the layer can be used.

In the case of calculating the refractive index of a layer formed using a mixed material, it may be directly measured or can be calculated by multiplying the ordinary refractive indices of films that are formed of only the individual materials by the percentages of the materials in the layer and summing up the products. Note that in the case where precise percentages cannot be obtained, a value obtained by dividing each of the ordinary refractive indices by the number of compositional components and summing up the quotients may be used.

Note that the light-emitting layer contains a light-emitting substance and a host material in some cases. In the case of calculating the refractive index of the light-emitting layer, the refractive index of a film of the host material and the value may be used as the refractive index of the light-emitting layer. The host material can be a material which can disperse a light-emitting substance as a guest material and may be a mixture.

In the light-emitting apparatus of one embodiment of the present invention with such a structure, light emitted from the light-emitting substance is reflected by the interface between layers with different refractive indices, which allows a larger amount of light to be reflected than in the case where light is reflected only by a reflective electrode, and improves external quantum efficiency. At the same time, the influence of surface plasmon in the reflective electrode can be decreased, which reduces energy loss to extract light efficiently. Furthermore, the subpixels include a common layer and are each adjusted to have a stacked-layer structure with a thickness allowing light emitted from the subpixel to be amplified; as a result, the emission efficiency of all emission colors can be improved easily, promptly, and inexpensively.

The light-emitting device S may include an electron-transport layer 114, an electron-injection layer 115, and the like between the light-emitting layer 113S and the second electrode 102. The light-emitting device L may include the electron-transport layer 114, the electron-injection layer 115, and the like between the light-emitting layer 113L and the second electrode 102. In addition, in each of the light-emitting device S and the light-emitting device L, a variety of functional layers such as a hole-injection layer, a hole-transport layer, a carrier-blocking layer, and an exciton-blocking layer may be provided between the first electrode 101 and the second electrode 102. The functional layers may be shared by light-emitting devices of all emission colors or may be independent of each other; the light-emitting apparatus is easily fabricated in the former case.

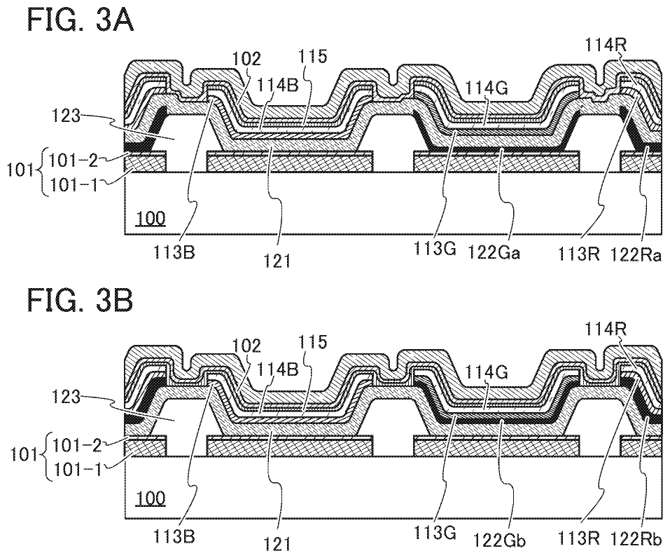

Next, FIG. 3A and FIG. 3B show examples in which the above structure is used for a light-emitting apparatus including three light-emitting devices of red, green, and blue. That is, FIG. 3A and FIG. 3B each show a light-emitting apparatus of one embodiment of the present invention including three subpixels in one pixel. Note that the same structures as those in FIG. 1 and FIG. 2 may be denoted by the same reference numerals, and the description thereof is omitted in some cases.

FIG. 3A and FIG. 3B clearly illustrate a reflective electrode 101-1 and a light-transmitting electrode (anode) 101-2 included in the first electrode 101. Light-emitting devices are formed in portions where the first electrode 101 and the second electrode 102 overlap with each other without an insulating layer 123 therebetween. In the drawings, a light-emitting device including a blue-light-emitting layer 113B is a blue-light-emitting device, a light-emitting device including a green-light-emitting layer 113G is a green-light-emitting device, and a light-emitting device including a red-light-emitting layer 113R is a red-light-emitting device; the blue-light-emitting device corresponds to a light-emitting device that exhibits an emission color with the shortest wavelength.

The blue-light-emitting device includes the first layer 121, the blue-light-emitting layer 113B, an electron-transport layer 114B, and the electron-injection layer 115 between the first electrode 101 and the second electrode 102. The thickness of the first layer 121 is adjusted to improve the light extraction efficiency of the blue-light-emitting device. It is preferable that the first layer 121 and the electron-injection layer 115 be continuously provided as provided as continuous layers shared by the blue-light-emitting device and other light-emitting devices.

The green-light-emitting device includes the first layer 121, a second layer 122G (a second layer 122Ga (FIG. 3A) and a second layer 122Gb (FIG. 3B), the green-light-emitting layer 113G containing a green light-emitting substance, an electron-transport layer 114G, and the electron-injection layer 115 between the first electrode 101 and the second electrode 102. The first layer 121 included in the green-light-emitting device has compositions and thicknesses similar to those of the first layer 121 included in the blue-light-emitting device. Thus, the first layer 121 in the blue-light-emitting device can be formed at the same time as the first layer 121 in the green-light-emitting device. As described above, the green-light-emitting device further includes the second layer 122G. By including the second layer 122G, the green-light-emitting device can have high emission efficiency as well as including the first layer 121 similar to the first layer 121 in the blue-light-emitting device.

The red light-emitting device includes the first layer 121, a second layer 122R (a second layer 122Ra (FIG. 3A) and a second layer 122Rb (FIG. 3B), the red-light-emitting layer 113R containing a red light-emitting substance, an electron-transport layer 114R, and the electron-injection layer 115 between the first electrode 101 and the second electrode 102. The first layer 121 included in the red-light-emitting device has compositions and thicknesses similar to those of the first layer 121 included in the blue-light-emitting device. Thus, the first layer 121 in the blue-light-emitting device can be formed at the same time as the first layer 121 in the red-light-emitting device. As described above, the red-light-emitting device further includes the second layer 122R. By including the second layer 122R, the red-light-emitting device can have high emission efficiency as well as including the first layer 121 similar to the first layer 121 in the blue-light-emitting device.

The blue-light-emitting layer 113B, the green-light-emitting layer 113G, and the red-light-emitting layer 113R contain different light-emitting substances, and the second layer 122G and the second layer 122R preferably have different thicknesses though they may have the same thickness or different thicknesses. The electron-transport layer 114B, the electron-transport layer 114G, and the electron-transport layer 114R may have similar structures or different structures. Although the electron-transport layers are separately illustrated in FIG. 3A and FIG. 3B, they may be formed continuously in the light-emitting devices when having similar structures. The electron-transport layer 114 may consist of a plurality of layers. In that case, one layer may be separately formed for each emission color and the other layers may be formed in common.

The second layer 122G and the second layer 122R correspond to the second layer 122 described with reference to FIG. 1 and may be low refractive index layers or high refractive index layers. Appropriate adjustment of the thicknesses depending on the emission colors can inhibit a decrease in emission efficiency or improve the emission efficiency in each light-emitting device easily, promptly, and inexpensively as well as enabling the light-emitting devices to share a layer with the blue-light-emitting device. In addition, when the stacked-layer structure is shared by the light-emitting devices emitting a plurality of emission colors, a light-emitting apparatus that has high emission efficiency and improved extraction efficiency of the light-emitting devices emitting a plurality of emission colors can be provided easily, promptly, and inexpensively.

### <Examples of High Refractive Index Material>

The first layer 121 is formed using an organic compound having a relatively high refractive index; such an organic compound is preferably a compound having a condensed aromatic hydrocarbon ring or a condensed heteroaromatic ring. The condensed aromatic hydrocarbon ring preferably has a naphthalene ring structure; for example, a naphthalene ring, an anthracene ring, a phenanthrene ring, or a triphenylene ring is preferably included in the condensed aromatic hydrocarbon ring, and the condensed heteroaromatic ring preferably has a structure of a carbazole ring, a dibenzofuran ring, or a dibenzothiophene ring. For example, benzo[b]naphtho[1,2-d]furan is preferable because of having a structure of a dibenzofuran ring.

It is preferable to use an organic compound having one or more elements of the third and later periods, an organic compound having a terphenyl skeleton, an organic compound having both of them, or the like. For example, a biphenyl group substituted by a naphthyl group, or a phenyl group substituted by a dibenzofuranyl group can be said to have a terphenyl skeleton. Specifically, N,N-bis[4-(6-phenylbenzo[b]naphtho[1,2-d]furan-8-yl)phenyl]-4-amino-p-terphenyl (abbreviation: BnfBB1TP), 4,4′-bis[4-(2-naphthyl)phenyl]-4″-phenyltriphenylamine (abbreviation: βNBiB1BP), N,N-bis[4-(dibenzofuran-4-yl)phenyl]-4-amino-p-terphenyl (abbreviation: DBfBB1TP), 4-[4′-(carbazol-9-yl)biphenyl-4-yl]-4′-(2-naphthyl)-4″-phenyltriphenylamine (abbreviation: YGTBiβNB), 5,5′-diphenyl-2,2′-di-5H-[1]benzothieno[3,2-c]carbazole (abbreviation: BisBTc), or the like can be suitably used.

### <Examples of Low Refractive Index Material>

The second layer 122 is formed using a substance with a relatively low refractive index; in general, a high carrier-transport property and a low refractive index have a trade-off relationship. This is because the carrier-transport property of an organic compound largely depends on an unsaturated bond, and an organic compound having many unsaturated bonds tends to have a high refractive index. Even having a low refractive index, a material with a low carrier-transport property causes a problem such as decreases in emission efficiency and reliability due to an increase in driving voltage or poor carrier balance, so that a light-emitting device with favorable characteristics cannot be obtained. Furthermore, even when a material has a sufficient carrier-transport property and a low refractive index, a highly reliable light-emitting device cannot be obtained if the material has a problem in glass transition temperature (Tg) or durability due to an unstable structure.

Thus, as an organic compound that can be used in the second layer 122, it is preferable to use a monoamine compound in which a first aromatic group, a second aromatic group, and a third aromatic group are included and the first aromatic group, the second aromatic group, and the third aromatic group are bonded to the same nitrogen atom. Since fluorenylamine has an effect of increasing the HOMO level, bonding of three fluorenes to nitrogen of the monoamine compound possibly increases the HOMO level significantly. In that case, a difference from the HOMO levels of peripheral materials becomes large, which might affect driving voltage, reliability, and the like. Thus, any one or two of the first aromatic group, the second aromatic group, and the third aromatic group are further preferably fluorene skeletons.

In the monoamine compound, the proportion of carbon atoms forming bonds by the sp3 hybrid orbitals to the total number of carbon atoms in the molecule is preferably higher than or equal to 23% and lower than or equal to 55%. In addition, it is preferable that the integral value of signals at lower than 4 ppm exceed the integral value of signals at 4 ppm or higher in the results of ¹H-NMR measurement conducted on the monoamine compound.

The monoamine compound preferably has at least one fluorene skeleton. One or more of the first aromatic group, the second aromatic group, and the third aromatic group are preferably fluorene skeletons. Since fluorenylamine has an effect of increasing the HOMO level, bonding of three fluorenes to nitrogen of the monoamine compound possibly increases the HOMO level significantly. In that case, a difference from the HOMO levels of peripheral materials (e.g., the HOMO level of the high refractive index material for the first layer 121) becomes large, which might affect driving voltage, reliability, and the like. Thus, any one or two of the first aromatic group, the second aromatic group, and the third aromatic group are further preferably fluorene skeletons.

Examples of the above-described organic compound having a hole-transport property include organic compounds having structures represented by General Formulae (Gₕ₁1) to (Gₕ₁4) below.

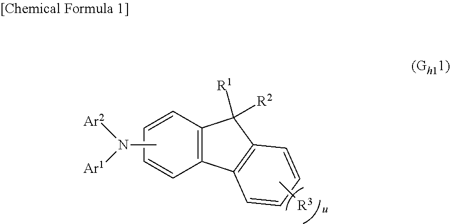

In General Formula (Gₕ₁1), Ar¹ and Ar² each independently represent a benzene ring or a substituent in which two or three benzene rings are bonded to each other. Note that one or both of Ar¹ and Ar² have one or more hydrocarbon groups each having 1 to 12 carbon atoms forming bonds only by the sp3 hybrid orbitals. The total number of carbon atoms contained in all of the hydrocarbon groups bonded to Ar¹ and Ar² is 8 or more and the total number of carbon atoms contained in all of the hydrocarbon groups bonded to Ar¹ or Ar² is 6 or more. Note that in the case where a plurality of straight-chain alkyl groups each having one or two carbon atoms are bonded to Ar¹ or Ar² as the hydrocarbon groups, the straight-chain alkyl groups may be bonded to each other to form a ring. As the hydrocarbon group having 1 to 12 carbon atoms forming bonds only by the sp3 hybrid orbitals, an alkyl group having 3 to 8 carbon atoms and a cycloalkyl group having 6 to 12 carbon atoms are preferable. Specifically, a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a heptyl group, an octyl group, a nonyl group, a decyl group, a cyclohexyl group, a 4-methylcyclohexyl group, a cycloheptyl group, a cyclooctyl group, a cyclononyl group, a cyclodecyl group, a decahydronaphthyl group, a cycloundecyl group, a cyclododecyl group, and the like can be used, and in particular, a tert-butyl group, a cyclohexyl group, and a cyclododecyl group are preferable.

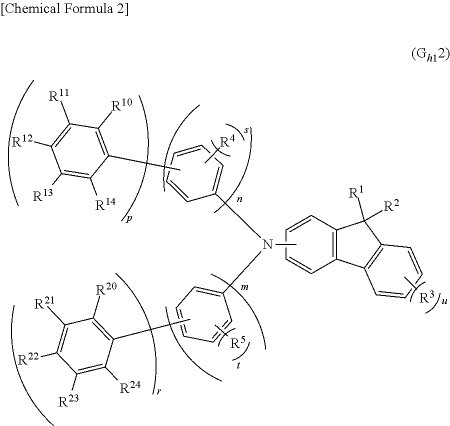

In General Formula (Gₕ₁2), m and r each independently represent 1 or 2 and m+r is 2 or 3. Furthermore, t independently represents an integer of 0 to 4 and is preferably 0. Moreover, R⁴ and R⁵ each independently represent hydrogen or any of hydrocarbon groups having 1 to 3 carbon atoms. When m is 2, the kind and number of substituents and the position of bonds included in one phenylene group may be the same as or different from those of the other phenylene group; and when r is 2, the kind and number of substituents and the position of bonds included in one phenyl group may be the same as or different from those of the other phenyl group. In the case where t is an integer of 2 to 4, R⁵s may be the same as or different from each other; and adjacent groups (adjacent R⁵s) may be bonded to each other to form a ring.

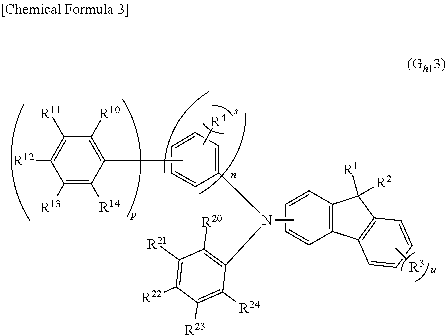

In General Formulae (Gₕ₁2) and (Gₕ₁3), n and p each independently represent 1 or 2 and n+p is 2 or 3. In addition, s independently represents an integer of 0 to 4 and is preferably 0. In the case where s is an integer of 2 to 4, R⁴s may be the same as or different from each other. Moreover, R⁴ represents hydrogen or any of hydrocarbon groups having 1 to 3 carbon atoms. When n is 2, the kind and number of substituents and the position of bonds in one phenylene group may be the same as or different from those of the other phenylene group; and when p is 2, the kind and number of substituents and the position of bonds in one phenyl group may be the same as or different from those of the other phenyl group. Examples of the hydrocarbon group having 1 to 3 carbon atoms include a methyl group, an ethyl group, a propyl group, and an isopropyl group.

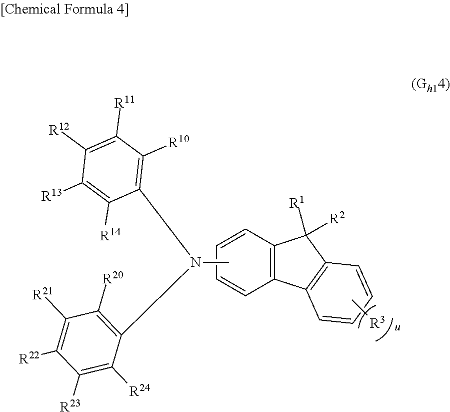

In General Formulae (Gₕ₁2) to (Gₕ₁4), R¹⁰ to R¹⁴ and R²⁰ to R²⁴ each independently represent hydrogen or a hydrocarbon group having 1 to 12 carbon atoms forming bonds only by the sp3 hybrid orbitals. Note that at least three of R¹⁰ to R¹⁴ and at least three of R²⁰ to R²⁴ are preferably hydrogen. As the hydrocarbon group having 1 to 12 carbon atoms forming bonds only by the sp3 hybrid orbitals, a tert-butyl group and a cyclohexyl group are preferable. The total number of carbon atoms contained in R¹⁰ to R¹⁴ and R²⁰ to R²⁴ is 8 or more and the total number of carbon atoms contained in either R¹⁰ to R¹⁴ or R²⁰ to R²⁴ is 6 or more. Adjacent groups of R¹⁰ to R¹⁴ and R²⁰ to R²⁴ may be bonded to each other to form a ring.

As the hydrocarbon group having 1 to 12 carbon atoms forming bonds only by the sp3 hybrid orbitals, an alkyl group having 3 to 8 carbon atoms and a cycloalkyl group having 6 to 12 carbon atoms are preferable. Specifically, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a heptyl group, an octyl group, a cyclohexyl group, a 4-methylcyclohexyl group, a cycloheptyl group, a cyclooctyl group, a cyclononyl group, a cyclodecyl group, a decahydronaphthyl group, a cycloundecyl group, a cyclododecyl group, and the like can be used, and in particular, a tert-butyl group, a cyclohexyl group, and a cyclododecyl group are preferable.

In General Formulae (Gₕ₁1) to (Gₕ₁4), u independently represents an integer of 0 to 4 and is preferably 0. In the case where u is an integer of 2 to 4, R's may be the same as or different from each other. In addition, R¹, R², and R³ each independently represent an alkyl group having 1 to 4 carbon atoms and R¹ and R² may be bonded to each other to form a ring. Examples of a hydrocarbon group having 1 to 4 carbon atoms include a methyl group, an ethyl group, a propyl group, and a butyl group.

An arylamine compound that has at least one aromatic group having first to third benzene rings and at least three alkyl groups is also preferable as one of the materials having a hole-transport property that can be used for the first layer 121 and the second layer 122. Note that the first to third benzene rings are bonded in this order and the first benzene ring is directly bonded to nitrogen of amine.

The first benzene ring may further include a substituted or unsubstituted phenyl group and preferably includes an unsubstituted phenyl group. Furthermore, the second benzene ring or the third benzene ring may include a phenyl group substituted by an alkyl group.

Note that hydrogen is not directly bonded to carbon atoms at 1- and 3-positions in two or more of, preferably all of the first to third benzene rings, and the carbon atoms are bonded to any of the first to third benzene rings, the phenyl group substituted by the alkyl group, the at least three alkyl groups, and the nitrogen of the amine.

It is preferable that the arylamine compound further include a second aromatic group. It is preferable that the second aromatic group have an unsubstituted monocyclic ring or a substituted or unsubstituted bicyclic or tricyclic condensed ring; in particular, it is further preferable that the second aromatic group be a group having a substituted or unsubstituted bicyclic or tricyclic condensed ring where the number of carbon atoms forming the ring is 6 to 13. Still further preferably, the second aromatic group is a group having a benzene ring, a naphthalene ring, a fluorene ring, or an acenaphthylene ring, and particularly preferably a group having a fluorene ring. Note that a dimethylfluorenyl group is preferable as the second aromatic group.

It is preferable that the arylamine compound further include a third aromatic group. The third aromatic group is a group having 1 to 3 substituted or unsubstituted benzene rings.

It is preferable that the at least three alkyl groups and the alkyl group substituted for the phenyl group be each a chain alkyl group having 2 to 5 carbon atoms. In particular, as the alkyl group, a chain alkyl group having a branch formed of 3 to 5 carbon atoms is preferable, and a tert-butyl group is further preferable.

Examples of the above-described material having a hole-transport property include organic compounds having structures represented by (Gₕ₂1) to (Gₕ₂3) below.

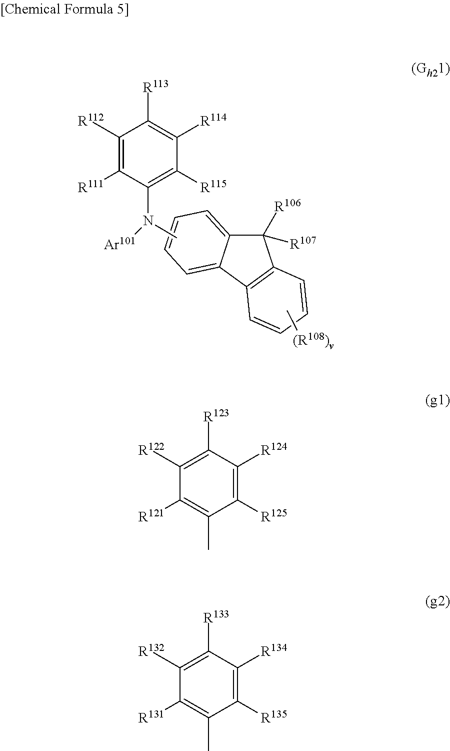

In General Formula (Gₕ₂1), Ar¹⁰¹ represents a substituted or unsubstituted benzene ring or a substituent in which two or three substituted or unsubstituted benzene rings are bonded to one another.

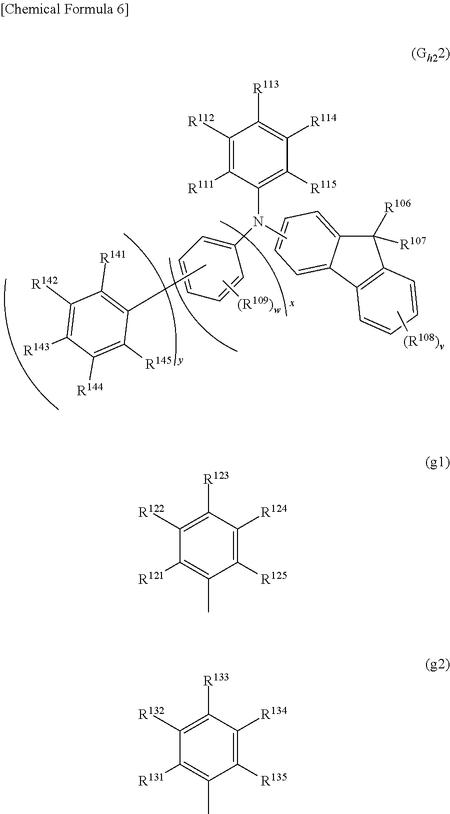

In General Formula (Gₕ₂2), x and y each independently represent 1 or 2 and x+y is 2 or 3. Furthermore, R¹⁰⁹ represents an alkyl group having 1 to 4 carbon atoms, and w represents an integer of 0 to 4. Moreover, R¹⁴¹ to R¹⁴⁵ each independently represent any one of hydrogen, an alkyl group having 1 to 6 carbon atoms, and a cycloalkyl group having 5 to 12 carbon atoms. When w is 2 or more, R¹⁰⁹s may be the same as or different from each other. When x is 2, the kind and number of substituents and the position of bonds included in one phenylene group may be the same as or different from those of the other phenylene group. When y is 2, the kind and number of substituents included in one phenyl group including R¹⁴¹ to R¹⁴⁵ may be the same as or different from those of the other phenyl group including R¹⁴¹ to R¹⁴⁵.

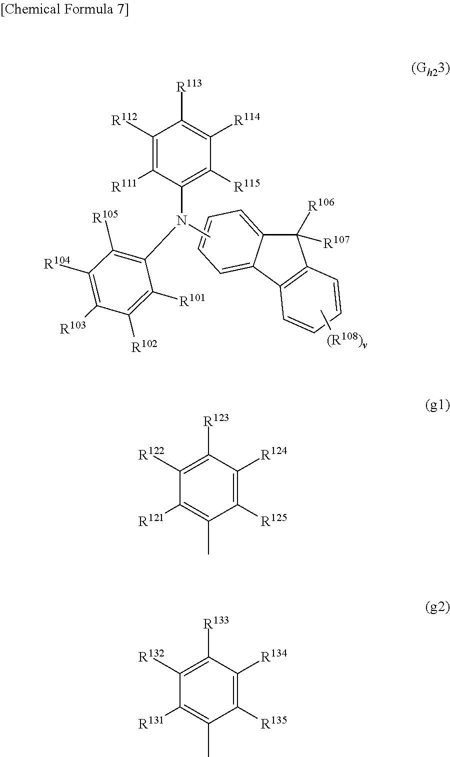

In General Formula (Gₕ₂3), R¹⁰¹ to R¹⁰⁵ each independently represent any one of hydrogen, an alkyl group having 1 to 6 carbon atoms, a cycloalkyl group having 6 to 12 carbon atoms, and a substituted or unsubstituted phenyl group.

In General Formulae (Gₕ₂1) to (Gₕ₂3), R¹⁰⁶, R¹⁰⁷, and R¹⁰⁸ each independently represent an alkyl group having 1 to 4 carbon atoms, and v represents an integer of 0 to 4. When v is 2 or more, R¹⁰⁸s may be the same as or different from each other. One of R¹¹¹ to R¹¹⁵ represents a substituent represented by General Formula (g1), and the others each independently represent any one of hydrogen, an alkyl group having 1 to 6 carbon atoms, and a substituted or unsubstituted phenyl group. In General Formula (g1), one of R¹²¹ to R¹²⁵ represents a substituent represented by General Formula (g2), and the others each independently represent any one of hydrogen, an alkyl group having 1 to 6 carbon atoms, and a phenyl group substituted by an alkyl group having 1 to 6 carbon atoms. In General Formula (g2), R¹³¹ to R¹³⁵ each independently represent any one of hydrogen, an alkyl group having 1 to 6 carbon atoms, and a phenyl group substituted by an alkyl group having 1 to 6 carbon atoms. Note that at least three of R¹¹¹ to R¹⁵, R¹²¹ to R¹²⁵, and R¹³¹ to R¹³⁵ are each an alkyl group having 1 to 6 carbon atoms; the number of substituted or unsubstituted phenyl groups in R¹¹¹ to R¹¹⁵ is one or less; and the number of phenyl groups substituted by an alkyl group having 1 to 6 carbon atoms in R¹²¹ to R¹²⁵ and R¹³¹ to R¹³⁵ is one or less. In at least two combinations of the three combinations R¹¹² and R¹¹⁴, R¹²² and R¹²⁴, and R¹³² and R¹³⁴, at least one R represents any of the substituents other than hydrogen.

In the case where the substituted or unsubstituted benzene ring or the substituted or unsubstituted phenyl group has a substituent in General Formulae (Gₕ₂1) to (Gₕ₂3), the substituent can be an alkyl group having 1 to 6 carbon atoms or a cycloalkyl group having 5 to 12 carbon atoms. The alkyl group having 1 to 4 carbon atoms is preferably a methyl group, an ethyl group, a propyl group, an isopropyl group, a butyl group, a sec-butyl group, an isobutyl group, or a tert-butyl group. The alkyl group having 1 to 6 carbon atoms is preferably a chain alkyl group having 2 or more carbon atoms; in terms of ensuring the hole-transport property, a chain alkyl group having 5 or less carbon atoms is preferable. A chain alkyl group having a branch and 3 or more carbon atoms is significantly effective in lowering the refractive index. That is, the alkyl group having 1 to 6 carbon atoms is preferably a chain alkyl group having 2 to 5 carbon atoms, and further preferably a chain alkyl group having a branch and 3 to 5 carbon atoms. As the alkyl group having 1 to 6 carbon atoms, a methyl group, an ethyl group, a propyl group, an isopropyl group, a butyl group, a sec-butyl group, an isobutyl group, a tert-butyl group, or a pentyl group is preferable, and a tert-butyl group is particularly preferable. As the cycloalkyl group having 5 to 12 carbon atoms, a cyclohexyl group, a 4-methylcyclohexyl group, a cycloheptyl group, a cyclooctyl group, a cyclononyl group, a cyclodecyl group, a decahydronaphthyl group, a cycloundecyl group, a cyclododecyl group, or the like can be used; a cycloalkyl group having 6 or more carbon atoms is preferable to lower the refractive index, and in particular, a cyclohexyl group and a cyclododecyl group are preferable.

The above-described organic compounds having a hole-transport property each have an ordinary refractive index higher than or equal to 1.40 and lower than or equal to 1.75 in a blue-light-emitting region (455 nm to 465 nm inclusive) or an ordinary refractive index higher than or equal to 1.40 and lower than or equal to 1.70 with respect to light having a wavelength of 633 nm, which is typically used for measurement of the refractive index. The organic compounds have both a high hole-transport property and a high Tg to achieve high reliability. These organic compounds also have a sufficient hole-transport property and thus can be suitably used as the materials for the second layer 122.

Preferable examples of such a material include N,N-bis(4-cyclohexylphenyl)-9,9-dimethyl-9H-fluoren-2-amine (abbreviation: dchPAF), N-[(4′-cyclohexyl)-1,1′-biphenyl-4yl]-N-(4-cyclohexylphenyl)-9,9-dimethyl-9H-fluoren-2-amine (abbreviation: chBichPAF), N,N-bis(4-cyclohexylphenyl)-N-(spiro[cyclohexane-1,9′[9H]fluoren]-2′yl)amine (abbreviation: dchPASchF), N-[(4′-cyclohexyl)-1,1′-biphenyl-4yl]-N-(4-cyclohexylphenyl)-N-(spiro[cyclohexane-1,9′-[9H]-fluoren]-2′yl)-amine (abbreviation: chBichPASchF), N-(4-cyclohexylphenyl)-bis(spiro[cyclohexane-1,9′-[9H]fluoren]-2′-yl)amine (abbreviation: SchFB1chP), N-[(3′,5′-ditertiarybutyl)-1,1′-biphenyl-4-yl]-N-(4-cyclohexylphenyl)-9,9-dimethyl-9H-fluoren-2-amine (abbreviation: mmtBuBichPAF), N,N-bis(3′,5′-ditertiarybutyl-1,1′-biphenyl-4-yl)-9,9-dimethyl-9H-fluoren-2-amine (abbreviation: dmmtBuBiAF), N-(3,5-ditertiarybutylphenyl)-N-(3′,5′-ditertiarybutyl-1,1′-biphenyl-4-yl)-9,9-dimethyl-9H-fluoren-2-amine (abbreviation: mmtBuBimmtBuPAF), N,N-bis(4-cyclohexylphenyl)-9,9-dipropyl-9H-fluoren-2-amine (abbreviation: dchPAPrF), N-[(3′,5′-dicyclohexyl)-1,1′-biphenyl-4-yl]-N-(4-cyclohexylphenyl)-9,9-dimethyl-9H-fluoren-2-amine (abbreviation: mmchBichPAF), N-(3,3″,5,5″-tetra-t-butyl-1,1′:3′,1″-terphenyl-5′-yl)-N-(4-cyclohexylphenyl)-9,9-dimethyl-9H-fluoren-2-amine (abbreviation: mmtBumTPchPAF), N-(4-cyclododecylphenyl)-N-(4-cyclohexylphenyl)-9,9-dimethyl-9H-fluoren-2-amine (abbreviation: CdoPchPAF), N-(3,3″,5,5″-tetra-t-butyl-1,1′:3′,1″-terphenyl-5′-yl)-N-phenyl-9,9-dimethyl-9H-fluoren-2-amine (abbreviation: mmtBumTPFA), N-(1,1′-biphenyl-4-yl)-N-(3,3″,5,5″-tetra-t-butyl-1,1′:3′,1″-terphenyl-5′-yl)-9,9-dimethyl-9H-fluoren-2-amine (abbreviation: mmtBumTPFBi), N-(1,1′-biphenyl-2-yl)-N-(3,3″,5,5″-tetra-t-butyl-1,1′:3′,1″-terphenyl-5′-yl)-9,9-dimethyl-9H-fluoren-2-amine (abbreviation: mmtBumTPoFBi), N-[(3,3′,5′-tri-t-butyl)-1,1′-biphenyl-5-yl]-N-(4-cyclohexylphenyl)-9,9-dimethyl-9H-fluoren-2-amine (abbreviation: mmtBumBichPAF), N-(1,1′-biphenyl-2-yl)-N-[(3,3′,5′-tri-t-butyl)-1,1′-biphenyl-5-yl]-9,9-dimethyl-9H-fluoren-2-amine (abbreviation: mmtBumBioFBi), N-(4-tert-butylphenyl)-N-(3,3″,5,5″-tetra-t-butyl-1,1′:3,1″-terphenyl-5′-yl)-9,9-dimethyl-9H-fluoren-2-amine (abbreviation: mmtBumTPtBuPAF), N-(3,3″,5′,5″-tetra-tert-butyl-1,1′:3,1″-terphenyl-5-yl)-N-phenyl-9,9-dimethyl-9H-fluoren-2-amine (abbreviation: mmtBumTPFA-02), N-(1,1′-biphenyl-4-yl)-N-(3,3″,5′,5″-tetra-tert-butyl-1,1′:3′,1″-terphenyl-5-yl)-9,9-dimethyl-9H-fluoren-2-amine (abbreviation: mmtBumTPFBi-02), N-(1,1′-biphenyl-2-yl)-N-(3,3″,5′,5″-tetra-tert-butyl-1,1′:3′,1″-terphenyl-5-yl)-9,9-dimethyl-9H-fluoren-2-amine (abbreviation: mmtBumTPoFBi-02), N-(4-cyclohexylphenyl)-N-(3,3″,5′,5″-tetra-tert-butyl-1,1′:3′,1″-terphenyl-5-yl)-9,9-dimethyl-9H-fluoren-2-amine (abbreviation: mmtBumTPchPAF-02), N-(1,1′-biphenyl-2-yl)-N-(3″,5′,5″-tri-tert-butyl-1,1′:3′,1″-terphenyl-5-yl)-9,9-dimethyl-9H-fluoren-2-amine (abbreviation: mmtBumTPoFBi-03), N-(4-cyclohexylphenyl)-N-(3″,5′,5″-tri-tert-butyl-1,1′:3′,1″-terphenyl-5-yl)-9,9-dimethyl-9H-fluoren-2-amine (abbreviation: mmtBumTPchPAF-03), N-(3″,5′,5″-tri-tert-butyl-1,1′:3′,1″-terphenyl-4-yl)-N-(1,1′-biphenyl-2-yl)-9,9-dimethyl-9H-fluoren-2-amine (abbreviation: mmtBumTPoFBi-04), N-(4-cyclohexylphenyl)-N-(3″,5′,5″-tri-tert-butyl-1,1′:3′,1″-terphenyl-4-yl)-9,9-dimethyl-9H-fluoren-2-amine (abbreviation: mmtBumTPchPAF-04), N-(1,1′-biphenyl-2-yl)-N-(3,3″,5″-tri-tert-butyl-1,1′:4′,1″-terphenyl-5-yl)-9,9-dimethyl-9H-fluoren-2-amine (abbreviation: mmtBumTPoFBi-05), N-(4-cyclohexylphenyl)-N-(3,3″,5″-tri-tert-butyl-1,1′:4′,1″-terphenyl-5-yl)-9,9-dimethyl-9H-fluoren-2-amine (abbreviation: mmtBumTPchPAF-05), and N-(3′,5′-ditertiarybutyl-1,1′-biphenyl-4-yl)-N-(1,1′-biphenyl-2-yl)-9,9-dimethyl-9H-fluoren-2-amine (abbreviation: mmtBuBioFBi).

Alternatively, 1,1-bis{4-[bis(4-methylphenyl)amino]phenyl}cyclohexane (abbreviation: TAPC) or the like can also be used.

### <GSP>

In one embodiment of the present invention, the light extraction efficiency is improved with a stack of a plurality of hole-transport layers having different refractive indices. However, the light-emitting device includes more layers than typical light-emitting devices, and thus includes more interfaces of layers, which might easily generate a resistance due to interfaces and increase driving voltage.

In a hole-transport region of an organic semiconductor device, holes generally need to be sequentially injected into layers formed of organic compounds with different HOMO levels between an active layer or a light-emitting layer and an electrode, in consideration of donation and acceptance of holes with the electrode. Since an excessively large difference in HOMO level between the layers naturally increases driving voltage, a difference in HOMO level is reduced by providing, between the electrode and the active layer (the light-emitting layer), layers formed of organic compounds having HOMO levels between the HOMO levels of the electrode and the active layer (the light-emitting layer). However, layers whose difference between HOMO levels is not so large may lead to a significant increase in driving voltage depending on a combination of organic compounds to be used. There has been no guideline for avoiding the above problem so far, and it has been considered that the cause of the problem is the incompatibility of materials.

A polar molecule and a non-polar molecule exist in an organic compound. The polar molecule has a permanent dipole moment. When the polar molecule is evaporated and the evaporated film has random orientation, unbalanced polarity is canceled out and polarization derived from the polarity of the molecule does not occur in the film. However, when the evaporated film has molecular orientation, the giant surface potential (GSP) derived from unbalanced polarization is sometimes observed.

The giant surface potential refers to a phenomenon in which the surface potential of an evaporated film increases in proportion to the film thickness, and can be described as spontaneous orientation polarization due to slight deviation of a permanent dipole moment of an organic compound to the thickness direction. In order to treat the surface potential as a value independent of the film thickness, a value obtained by dividing the surface potential of an evaporated film by the film thickness, that is, the potential gradient (slope) of the surface potential of the evaporated film, is used. In this specification, the potential gradient of the surface potential of the evaporated film is denoted by the slope of GSP (mV/nm).

The consideration of the value of the slope of GSP can eliminate the mismatch that has been thought to be caused by the aforementioned incompatibility of materials and enables an organic semiconductor device with excellent properties to be easily obtained.

In the light-emitting device S, the value obtained by subtracting the slope of GSP of the light-emitting layer 113S from the slope of GSP of the first layer 121 is preferably less than or equal to 10 (mV/nm), further preferably less than or equal to 0 (mV/nm).

In the light-emitting device L, the value obtained by subtracting the slope of GSP of the light-emitting layer 113L from the slope of GSP of the first layer 121 is preferably less than or equal to 10 (mV/nm), further preferably less than or equal to 0 (mV/nm).

In the case where the light-emitting device L includes the second layer 122 (the second layer 122a) between the first layer 121 and the first electrode 101, the value obtained by subtracting the slope of GSP of the first layer 121 from the slope of GSP of the second layer 122a is preferably less than or equal to 10 (mV/nm), further preferably less than or equal to 0 (mV/nm).

In the case where the light-emitting device L includes the second layer 122 (the second layer 122b) between the light-emitting layer 113L and the first layer 121, the value obtained by subtracting the slope of GSP of the second layer 122b from the slope of GSP of the first layer 121 is preferably less than or equal to 10 (mV/nm), further preferably less than or equal to 0 (mV/nm).

With such a structure, a light-emitting device having excellent properties such as a low driving voltage, low power consumption, or a high power efficiency can be easily obtained.

Furthermore, the slope of GSP of the light-emitting layer 113S is preferably larger than the slope of GSP of the first layer 121. The slope of GSP of the light-emitting layer 113L is preferably larger than the slope of GSP of the first layer 121. The slope of GSP of the first layer 121 is preferably larger than the slope of GSP of the second layer 122a. The slope of GSP of the second layer 122b is preferably larger than the slope of GSP of the first layer 121. With such a structure, a light-emitting device having excellent properties such as a low driving voltage, low power consumption, or a high power efficiency can be obtained more easily.

Note that the slope of GSP of each layer can be obtained by measurement of the slope of GSP of an evaporated film of a material (an organic compound) in the layer.

A method for obtaining the slope of GSP of an organic compound will be described.

In general, the slope of a plot of the surface potential of an evaporated film in the thickness direction by Kelvin probe measurement is assumed as the level of the giant surface potential, that is, the slope of GSP (mV/nm); in the case where two different layers are stacked, a change in the density of polarization charges (mC/m²) accumulated at the interface, which is in association with the slope of GSP, can be utilized to estimate the slope of GSP.

The article “Spontaneous Orientation Polarization of Polar Molecules and Interface Properties of Organic Electronic Devices”, Journal of the Vacuum Society of Japan, 2015, Vol. 58, No. 3, which is written by Y. Noguchi et al., discloses that the following formulae hold when current is made to flow through a stack of organic thin films (a thin film 1 and a thin film 2; note that the thin film 1 is positioned on the anode side and the thin film 2 is positioned on the cathode side) with different kinds of spontaneous polarization.

$$\begin{matrix}[ Formula 1 ] & \\ {σ}_{if} = \frac{{Q}_{if}}{S} = ( {V}_{i} - {V}_{bi} ) \frac{{ε}_{2}}{{d}_{2}} & ( 1 )\end{matrix}$$

$$\begin{matrix}[ Formula 2 ] & \\ {σ}_{if} = {P}_{1} - {P}_{2} = \frac{{ε}_{1} {V}_{1}}{{d}_{1}} - \frac{{ε}_{2} {V}_{2}}{{d}_{2}} & ( 2 )\end{matrix}$$

In Formula (1), σ_{if} is a polarization charge density, Vᵢ is a hole-injection voltage, V_{bi} is a threshold voltage, d₂ is the thickness of the thin film 2, and ε₂ is the dielectric constant of the thin film 2. Note that Vᵢ and V_{bi} can be estimated from the capacity-voltage characteristics of a device. The square of an ordinary refractive index nₒ(633 nm) can be used as the dielectric constant. As described above, according to Formula (1), the polarization charge density σ_{if} can be calculated using Vᵢ and V_{bi} estimated from the capacity-voltage characteristics, the dielectric constant ε₂ of the thin film 2 calculated from the refractive index, and the thickness d₂ of the thin film 2.

Next, in Formula (2), σ_{if} is a polarization charge density, Pₙ is the slope of GSP of a thin film n, and εₙ is the dielectric constant of the thin film n. Since the polarization charge density σ_{if} can be obtained from Formula (1) above, the use of a substance with known GSP for the thin film 2 enables the slope of GSP of the thin film 1 to be estimated.

In this manner, an evaporated film of an organic compound with the slope of GSP to be obtained is formed as the thin film 1, and the slope of GSP can be obtained by the above method.

Note that in this specification, Alq₃ whose slope of GSP is known to be 48 (mV/nm) is used for the thin film 2, and the slope of GSP of each thin film is obtained.

The orientation of an evaporated film is known to depend on the substrate temperature in evaporation, and the value of the slope of GSP also possibly depends on the substrate temperature in evaporation. The measured values in this specification are values of films evaporated with the substrate temperature set to room temperature in evaporation.

### <Structure of Light-Emitting Device>

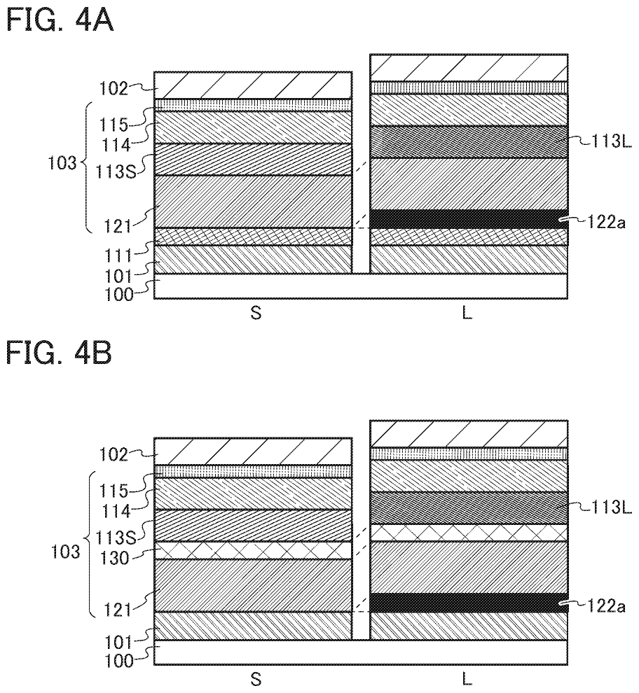

Next, structures and materials of the light-emitting devices included in the light-emitting apparatus of one embodiment of the present invention will be described in detail with reference to FIG. 4A. Note that in FIG. 4, the same structures as those in FIG. 1 and FIG. 2 may be denoted by the same reference numerals, and the description thereof is omitted in some cases. As described above, in the light-emitting apparatus of one embodiment of the present invention, the light-emitting device that exhibits emission colors with a short wavelength includes the first layer 121 and the light-emitting layer 113S between the pair of electrodes of the first electrode 101 and the second electrode 102, and the light-emitting device that exhibits emission colors with a long wavelength includes the first layer 121, the second layer 122, and the light-emitting layer 113L between the pair of electrodes of the first electrode 101 and the second electrode 102. The first layer 121 and the second layer 122 are positioned between the light-emitting layer 113 and the first electrode 101. Note that in this specification, a plurality of layers positioned between the first electrode 101 and the second electrode 102 in the light-emitting device are collectively referred to as an EL layer 103 in some cases. In this case, for example, it can be said that the light-emitting device that exhibits an emission color with a short wavelength includes at least the first layer 121 and the light-emitting layer 113S as the EL layer 103, and the light-emitting device that exhibits an emission color with a long wavelength includes at least the first layer 121, the second layer 122, and the light-emitting layer 113L as the EL layer 103. In this specification, the light-emitting layer 113S and the light-emitting layer 113L are collectively referred to as the light-emitting layer 113 in some cases.

The light-emitting layer 113 (the light-emitting layer 113S and the light-emitting layer 113L) contains a light-emitting substance. The first electrode 101 preferably includes a reflective electrode and further preferably has a stacked-layer structure including an anode. In that case, the anode preferably has a property of transmitting visible light and is provided between the reflective electrode and the first layer 121 so as to be in contact with the reflective electrode.

The anode is preferably formed using any of metals, alloys, and conductive compounds with a high work function (specifically, higher than or equal to 4.0 eV), mixtures thereof, and the like. Specific examples include indium oxide-tin oxide (ITO: Indium Tin Oxide), indium oxide-tin oxide containing silicon or silicon oxide, indium oxide-zinc oxide, and indium oxide containing tungsten oxide and zinc oxide (IWZO). Such conductive metal oxide films are usually formed by a sputtering method, but may be formed by application of a sol-gel method or the like. In an example of the formation method, indium oxide-zinc oxide is formed by a sputtering method using a target obtained by adding 1 to 20 wt % of zinc oxide to indium oxide. Furthermore, indium oxide containing tungsten oxide and zinc oxide (IWZO) can be formed by a sputtering method using a target in which tungsten oxide and zinc oxide are added to indium oxide at 0.5 to 5 wt % and 0.1 to 1 wt %, respectively. Other examples of the material used for the anode include gold (Au), platinum (Pt), nickel (Ni), tungsten (W), chromium (Cr), molybdenum (Mo), iron (Fe), cobalt (Co), copper (Cu), palladium (Pd), and nitride of a metal material (e.g., titanium nitride). Graphene can also be used for the anode. Note that when a composite material described later is used for a layer (typically, a hole-injection layer) that is in contact with the anode, an electrode material can be selected regardless of its work function.

The reflective electrode has a visible light reflectivity of 40% to 100%, preferably 70% to 100% and a resistivity of 1×10⁻² Ωcm or lower. Examples of the material for the reflective electrode include aluminum (Al) and an alloy containing Al. Examples of the alloy containing Al include an alloy containing Al and L (L represents one or more of titanium (Ti), neodymium (Nd), nickel (Ni), and lanthanum (La)), such as an alloy containing Al and Ti and an alloy containing Al, Ni, and La. Aluminum has low resistance and high light reflectivity. Aluminum is included in earth's crust in large amount and is inexpensive; therefore, use of aluminum can reduce costs for manufacturing a light-emitting device with aluminum. Alternatively, silver (Ag), an alloy of Ag and N (N represents one or more of yttrium (Y), Nd, magnesium (Mg), ytterbium (Yb), Al, Ti, gallium (Ga), zinc (Zn), indium (In), tungsten (W), manganese (Mn), tin (Sn), iron (Fe), Ni, copper (Cu), palladium (Pd), iridium (Ir), and gold (Au)), or the like can be used. Examples of the alloy containing silver include an alloy containing silver, palladium, and copper, an alloy containing silver and copper, an alloy containing silver and magnesium, an alloy containing silver and nickel, an alloy containing silver and gold, and an alloy containing silver and ytterbium. Besides, a transition metal such as tungsten, chromium (Cr), molybdenum (Mo), copper, or titanium can be used.

The EL layer 103 preferably has a stacked-layer structure, and there is no particular limitation on the stacked-layer structure as long as the light-emitting layer 113, the first layer 121, and the second layer 122 are included. For the EL layer 103, various functional layers such as a hole-injection layer, a hole-transport layer, an electron-transport layer, an electron-injection layer, a carrier-blocking layer (a hole-blocking layer or an electron-blocking layer), an exciton-blocking layer, an intermediate layer, and a charge-generation layer can be used as appropriate. Note that the first layer 121 and the second layer 122 function as a hole-injection layer, a hole-transport layer, an electron-blocking layer, or the like.

With reference to FIG. 4A, the structure is described in which a hole-injection layer 111, the electron-transport layer 114, and the electron-injection layer 115 are included in addition to the light-emitting layer 113 (the light-emitting layer 113S or the light-emitting layer 113L), the first layer 121, and the second layer 122. In FIG. 4A, the first layer 121 and the second layer 122 function as a hole-transport layer.

The hole-injection layer 111 is provided in contact with the anode and has a function of facilitating injection of holes into the EL layer 103. The hole-injection layer can be formed using phthalocyanine (abbreviation: H₂Pc), a phthalocyanine-based complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), a high molecular compound such as poly(3,4-ethylenedioxythiophene)/(polystyrenesulfonic acid) (abbreviation: PEDOT/PSS), or the like.

The hole-injection layer may be formed using a substance having an electron-acceptor property. Examples of the substance having an acceptor property include an organic compound having an electron-withdrawing group (a halogen group, a cyano group, or the like), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group or a halogen group such as a fluoro group) has a very high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, transition metal oxide such as molybdenum oxide, vanadium oxide, ruthenium oxide, tungsten oxide, or manganese oxide can also be used, other than the above-described organic compounds. The substance having an acceptor property can extract electrons from an adjacent hole-transport layer (or hole-transport material) by voltage application between the electrodes.

The hole-injection layer may be formed using a composite material containing any of the aforementioned materials having an acceptor property and a material having a hole-transport property. As the material having a hole-transport property that is used in the composite material, any of a variety of organic compounds such as aromatic amine compounds, heteroaromatic compounds, aromatic hydrocarbons, and high molecular compounds (e.g., oligomers, dendrimers, or polymers) can be used. Note that the material having a hole-transport property that is used in the composite material preferably has a hole mobility of 1×10⁻⁶ cm²/Vs or higher. The material having a hole-transport property that is used in the composite material is preferably a compound having a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further condensed to the carbazole ring or the dibenzothiophene ring is preferable.

The material having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the material having a hole-transport property preferably has an N,N-bis(4-biphenyl)amino group because a light-emitting device having a long lifetime can be fabricated. Specific examples of such a material having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6; 1′-binaphthyl-2-yl)triphenylamine (abbreviation: BBAαNβNB), 4,4′-diphenyl-4″-(7; 1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6; 2′-binaphthyl-2-yl)triphenylamine (abbreviation: BBA(βN2)B), 4,4′-diphenyl-4″-(7; 2′-binaphthyl-2-yl)triphenylamine (abbreviation: BBA(βN2)B-03), 4,4′-diphenyl-4″-(4; 2′-binaphthyl-1-yl)triphenylamine (abbreviation: BBAβNαNB), 4,4′-diphenyl-4″-(5; 2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis([1,1′-biphenyl]-4-yl)-9,9′-spirobi[9H-fluoren]-2-amine (abbreviation: BBASF), N,N-bis([1,1′-biphenyl]-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(4-biphenyl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

As the material having a hole-transport property, the following aromatic amine compounds can also be used: N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

As the material having a hole-transport property in the above composite material, it is also possible to use any of the aforementioned organic compounds having a low refractive index, which can be used for the first layer 121 and the second layer 122 that has a low refractive index. In the case where the composite material containing the organic compound as the material having a hole-transport property is used for the first layer 121, the first layer 121 can function as a hole-transport layer. In the case where the second layer 122 (e.g., the second layer 122a in FIG. 1A) is provided between the first electrode 101 and the first layer 121 and the composite material containing the organic compound as the material having a hole-transport property is used for the second layer 122a, the second layer 122a can function as a hole-injection layer. Note that in that case, the hole-injection layer 111 is not necessarily formed between the first layer 121 and the first electrode 101.

Further preferably, the material having a hole-transport property that is used in the composite material has a relatively deep HOMO level higher than or equal to −5.7 eV and lower than or equal to −5.4 eV. When the material having a hole-transport property that is used in the composite material has a relatively deep HOMO level, holes can be easily injected into the hole-transport layer to easily provide a light-emitting device having a long lifetime. In addition, when the material having a hole-transport property that is used in the composite material has a relatively deep HOMO level, induction of holes can be inhibited properly so that a light-emitting device having a longer lifetime can be obtained.

Forming the hole-injection layer 111 or making the first layer 121 or the second layer 122 function as a hole-injection layer can improve the hole-injection property, offering the light-emitting device with a low driving voltage.

Among substances having an acceptor property, an organic compound having an acceptor property is easy to use because it is easily deposited by vapor deposition.

The hole-transport layer is formed using a material having a hole-transport property. The material having a hole-transport property preferably has a hole mobility higher than or equal to 1×10⁻⁶ cm²/Vs. As described above, the first layer 121 and the second layer 122 function as the hole-transport layer of the light-emitting device in FIG. 4A. With this structure, the light-emitting device with high emission efficiency can be obtained. For example, one or more of the external quantum efficiency, the current efficiency, and the blue index of the light-emitting device can be improved.

An electron-blocking layer 130 may be provided between the light-emitting layer 113 and the first layer 121 and the second layer 122 as illustrated in FIG. 4B. The electron-blocking layer is preferably formed using an organic compound that has a hole-transport property and a higher lowest unoccupied molecular orbital (LUMO) level than a host material of the light-emitting layer 113 by 0.25 eV or more. In the case where an organic compound that is the above organic compound and can be used for the second layer 122 is used for the second layer 122b, the second layer 122b can also function as an electron-blocking layer.

Although FIG. 4A illustrates an example in which the hole-injection layer 111 and the first layer 121 are provided between the first electrode 101 and the light-emitting layer 113, the first layer 121 may be formed in contact with the first electrode 101 without the hole-injection layer 111 being provided, and the first layer 121 (or the second layer 122) may function as a hole-injection layer.

The light-emitting layer 113 preferably contains a light-emitting substance and a host material. The light-emitting layer 113 may additionally contain other materials. Alternatively, the light-emitting layer 113 may be a stack of two layers with different compositions.

The light-emitting substance may be a fluorescent substance, a phosphorescent substance, a substance exhibiting thermally activated delayed fluorescence (TADF), or other light-emitting substances.

Examples of the material that can be used as a fluorescent substance in the light-emitting layer 113 are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N-(1,6-pyrene-diyl)bis[(6-phenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b; 6,7-b′]bisbenzofuran (abbreviation: 3,10PCA2Nbf(IV)-02), and 3,10-bis[N-(dibenzofuran-3-yl)-N-phenylamino]naphtho[2,3-b; 6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

Examples of the material that can be used when a phosphorescent substance is used as the light-emitting substance in the light-emitting layer 113 are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-N2]phenyl-KC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), or tris[4-(3-biphenyl)-5-isopropyl-3-phenyl-4H-1,2,4-triazolato]iridium(III) (abbreviation: [Ir(iPrptz-3b)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) or tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[(1-2,6-diisopropylphenyl)-2-phenyl-1H-imidazole]iridium(III) (abbreviation: [Ir(iPrpmi)₃]) or tris[3-(2,6-dimethylphenyl)-7-methylimidazo[1,2-f]phenanthridinato]iridium(III) (abbreviation: [Ir(dmpimpt-Me)₃]); and an organometallic iridium complex in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), or bis[2-(4′,6′-difluorophenyl)pyridinato-N,C^{2′}]iridium(III) acetylacetonate (abbreviation: FIracac). These compounds exhibit blue phosphorescent light and have an emission peak in the wavelength range of 450 nm to 520 nm.

Other examples include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-xN2)phenyl-κC]iridium(III) (abbreviation: Ir(5mppy-d₃)₂(mbfpypy-d₃)), [2-(methyl-d₃)-8-[4-(1-methylethyl-1-d)-2-pyridinyl-κN]benzofuro[2,3-b]pyridin-7-yl-κC]bis[5-(methyl-d₃)-2-[5-(methyl-d₃)-2-pyridinyl-1N]phenyl-κC]iridium(III) (abbreviation: Ir(5mtpy-d₆)₂(mbfpypy-iPr-d₄)), [2-d₃-methyl-(2-pyridinyl-κN)benzofuro[2,3-b]pyridine-κC]bis[2-(2-pyridinyl-xlN)phenyl-κC]iridium(III) (abbreviation: Ir(ppy)₂(mbfpypy-d₃)), or [2-(4-methyl-5-phenyl-2-pyridinyl-xN)phenyl-KC]bis[2-(2-pyridinyl-xN)phenyl-κC]iridium(III) (abbreviation: Ir(ppy)₂(mdppy)); and a rare earth metal complex such as tris(acetylacetonato) (monophenanthroline)terbium(III) (abbreviation: [Tb(acac)₃(Phen)]). These are mainly compounds that exhibit green phosphorescent light and have an emission peak in the wavelength range of 500 nm to 600 nm. Note that organometallic iridium complexes having a pyrimidine skeleton have distinctively high reliability or emission efficiency and thus are particularly preferable.

Other examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d₁npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]) or bis(1-phenylisoquinolinato-N,C^{2′})iridium(III) acetylacetonate (abbreviation: [Ir(piq)₂(acac)]); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) ortris[l-(2-thenoyl)-3,3,3-trifluoroacetonato](monophenanthroline)europium(III) (abbreviation: [Eu(TTA)₃(Phen)]). These compounds exhibit red phosphorescent light and have an emission peak in the wavelength range of 600 nm to 700 nm. Organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given as an example. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

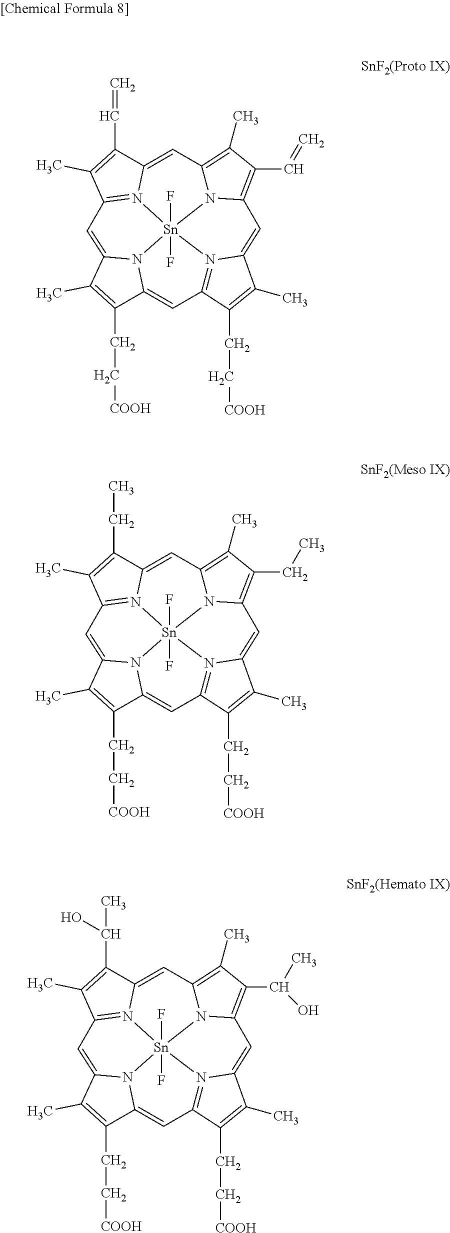

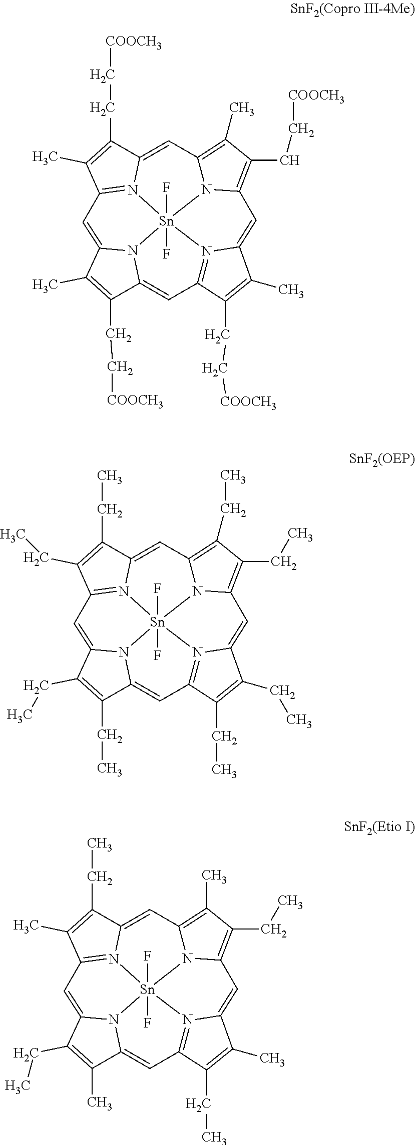

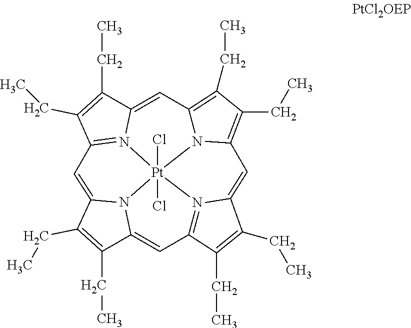

Alternatively, a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having excellent electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring having a cyano group or a nitrile group such as benzonitrile or cyanobenzene, a heteroaromatic ring, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

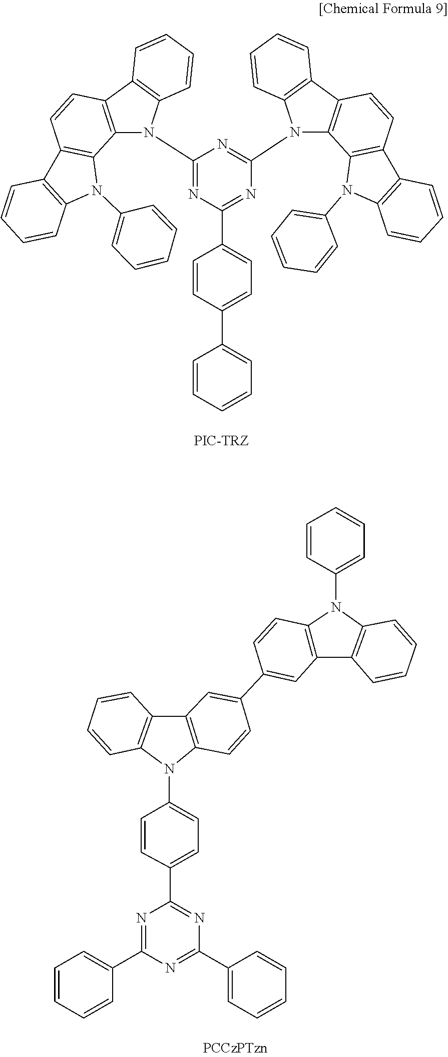 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

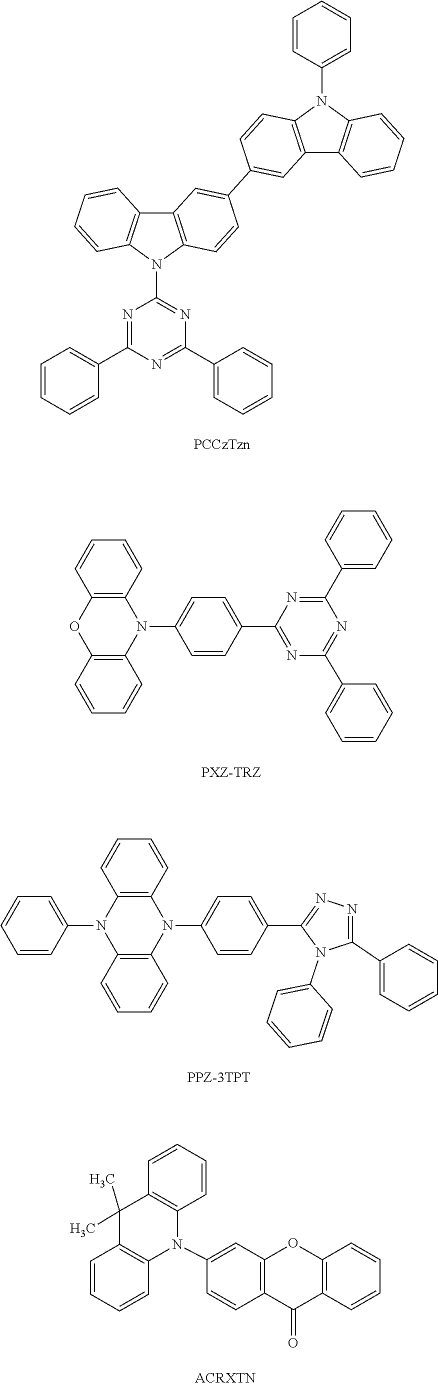 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21]

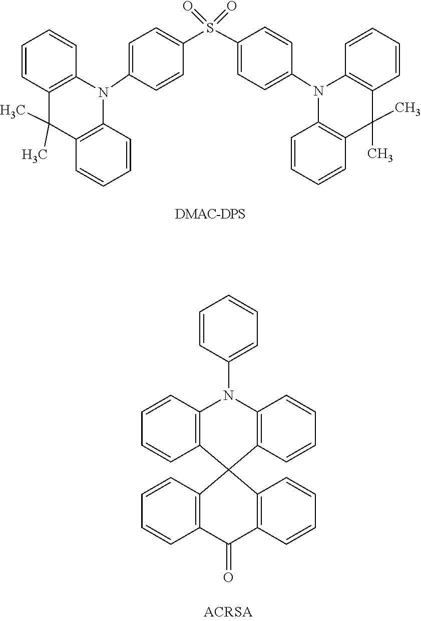

As the TADF material, a TADF material whose singlet excited state and triplet excited state are in a thermal equilibrium state may be used. Such a TADF material has a short emission lifetime (excitation lifetime), which allows inhibiting a decrease in efficiency in a high-luminance region of a light-emitting device. Specifically, a material having the following molecular structure can be used.

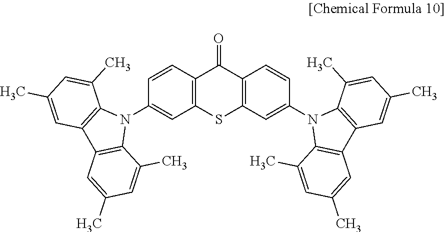

Note that a TADF material is a material having a small difference between the S1 level and the T1 level and a function of converting triplet excitation energy into singlet excitation energy by reverse intersystem crossing. Thus, it is possible to upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than the S1 level of the TADF material. In addition, the T1 level of the host material is preferably higher than the T1 level of the TADF material.

As the host material in the light-emitting layer, various carrier-transport materials such as materials having an electron-transport property and/or materials having a hole-transport property, and the TADF materials can be used.

The material having a hole-transport property is preferably an organic compound having an amine skeleton or a π-electron rich heteroaromatic ring skeleton, for example. Examples of the material include a compound having an aromatic amine skeleton, such as 4,4′-bis[N-(1-naphthyl)-N-phenylamino]biphenyl (abbreviation: NPB), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used.

As the material having an electron-transport property, for example, a metal complex such as bis(10-hydroxybenzo[h]quinolinato)beryllium(II) (abbreviation: BeBq2), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferable. Examples of the organic compound having a π-electron deficient heteroaromatic ring include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: COl1), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: Bphen), bathocuproine (abbreviation: BCP), 2,9-di(naphthalen-2-yl)-4,7-diphenyl-1,10-phenanthroline (abbreviation: NBphen), or 2,2-(1,3-phenylene)bis[9-phenyl-1,10-phenanthroline] (abbreviation: mPPhen2P); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[(3′-dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(1,1′-biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)₂Py), 2,2′-(pyridine-2,6-diyl)bis{4-[4-(2-naphthyl)phenyl]-6-phenylpyrimidine} (abbreviation: 2,6(NP-PPm)₂Py), 6-(1,1′-biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(1,1′-biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)-1,1′-biphenyl-3-yl]-4,6-diphenyl-1,3,5-triazine (abbreviation: mFBPTzn), 5-[3-(4,6-diphenyl-1,3,5-triazin-2yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris(3′-(pyridin-3-yl)biphenyl-3-yl)-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)-1,1′-biphenyl-3-yl]-4,6-diphenyl′1,3,5-triazine (abbreviation: mTpBPTzn), 9-[4-(4,6-diphenyl-1,3,5-triazin-2-yl)-2-dibenzothiophenyl]-2-phenyl-9H-carbazole (abbreviation: PCDBfTzn), or 2-[1,1′-biphenyl]-3-yl-4-phenyl-6-(8-[1,1′:4′,1″-terphenyl]-4-yl-1-dibenzofuranyl)-1,3,5-triazine (abbreviation: mBP-TPDBfTzn). Among the above materials, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S1 level of the TADF material is preferably higher than the S1 level of the fluorescent substance in order that high emission efficiency can be achieved. Furthermore, the Ti level of the TADF material is preferably higher than the S1 level of the fluorescent substance. Therefore, the T1 level of the TADF material is preferably higher than the T1 level of the fluorescent substance.

It is also preferable to use a TADF material that emits light whose wavelength overlaps with the wavelength on a lowest-energy-side absorption band of the fluorescent substance. This case is preferable because excitation energy is transferred smoothly from the TADF material to the fluorescent substance and light emission can be obtained efficiently.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton which causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, so that the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring. Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. As the substance having an anthracene skeleton that is used as the host material, a substance having a diphenylanthracene skeleton, in particular, a substance having a 9,10-diphenylanthracene skeleton, is chemically stable and thus is preferably used. The host material preferably has a carbazole skeleton because the hole-injection and hole-transport properties are improved; further preferably, the host material has a benzocarbazole skeleton in which a benzene ring is further condensed to carbazole because the HOMO level thereof is shallower than that of carbazole by approximately 0.1 eV and thus holes enter the host material easily. In particular, the host material preferably has a dibenzocarbazole skeleton because the HOMO level thereof is shallower than that of carbazole by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole skeleton or a dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), 9-(1-naphthyl)-10-[4-(2-naphthyl)phenyl]anthracene (abbreviation: (αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)-benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-[4-(10-[1,1′-biphenyl]-4-yl-9-anthracenyl)phenyl]-2-ethyl-1H-benzimidazole (abbreviation: EtBImPBPhA). In particular, CzPA, cgDBCzPA, 2mBnfPPA, and PCzPA exhibit excellent properties and thus are preferably selected.

The host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission overlapping with the wavelength of a lowest-energy-side absorption band of the light-emitting substance, in which case energy can be transferred smoothly and light emission can be obtained efficiently. The use of such a structure is preferable because the driving voltage can also be reduced.

At least one of the materials forming an exciplex may be a phosphorescent substance. In this case, triplet excitation energy can be efficiently converted into singlet excitation energy by reverse intersystem crossing.

Combination of a material having an electron-transport property and a material having a hole-transport property whose HOMO level is higher than or equal to that of the material having an electron-transport property is preferable for forming an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of a mixed film in which the material having a hole-transport property and the material having an electron-transport property are mixed is shifted to a longer wavelength than the emission spectrum of each of the materials (or has another peak on the longer wavelength side) observed in comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL of each of the materials, observed in comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed in comparison of the transient EL of the material having a hole-transport property, the transient EL of the material having an electron-transport property, and the transient EL of the mixed film of these materials.

The electron-transport layer 114 contains a substance having an electron-transport property. The material having an electron-transport property is preferably a substance having an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound having a t-electron deficient heteroaromatic ring is preferable as the above organic compound. The organic compound having a Ti-electron deficient heteroaromatic ring is preferably one or more of an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

Specific examples of the material having an electron-transport property that can be used for the above electron-transport layer include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: COl1), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: Bphen), bathocuproine (abbreviation: BCP), 2,9-di(naphthalen-2-yl)-4,7-diphenyl-1,10-phenanthroline (abbreviation: NBphen), or 2,2-(1,3-phenylene)bis[9-phenyl-1,10-phenanthroline] (abbreviation: mPPhen2P); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[(3′-dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(1,1′-biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)₂Py), 2,2′-(pyridine-2,6-diyl)bis{4-[4-(2-naphthyl)phenyl]-6-phenylpyrimidine} (abbreviation: 2,6(NP-PPm)₂Py), 6-(1,1′-biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(1,1′-biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a triazine skeleton, such as 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)-1,1′-biphenyl-3-yl]-4,6-diphenyl-1,3,5-triazine (abbreviation: mFBPTzn), 5-[3-(4,6-diphenyl-1,3,5-triazin-2yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris(3′-(pyridin-3-yl)biphenyl-3-yl)-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)-1,1′-biphenyl-3-yl]-4,6-diphenyl′1,3,5-triazine (abbreviation: mTpBPTzn), 9-[4-(4,6-diphenyl-1,3,5-triazin-2-yl)-2-dibenzothiophenyl]-2-phenyl-9H-carbazole (abbreviation: PCDBfTzn), or 2-[1,1′-biphenyl]-3-yl-4-phenyl-6-(8-[1,1′:4′,1″-terphenyl]-4-yl-1-dibenzofuranyl)-1,3,5-triazine (abbreviation: mBP-TPDBfTzn). Among the above materials, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage.

In the case where the organic compound having an electron-transport property is used for the electron-transport layer 114, the electron-transport layer 114 preferably includes a metal complex of an alkali metal or an alkaline earth metal. A heterocyclic compound having a diazine skeleton, a heterocyclic compound having a triazine skeleton, and a heterocyclic compound having a pyridine skeleton are particularly preferable in terms of driving lifetime because they are likely to form an exciplex with an organometallic complex of an alkali metal with stable energy (the emission wavelength of the exciplex easily becomes longer). In particular, the heterocyclic compound having a diazine skeleton or the heterocyclic compound having a triazine skeleton has a deep LUMO level and thus is preferable for stabilization of energy of an exciplex.

The organometallic complex of an alkali metal is preferably a metal complex of sodium or lithium. Alternatively, the organometallic complex of an alkali metal preferably has a ligand having a quinolinol skeleton. Further preferably, the organometallic complex of an alkali metal is preferably a lithium complex having an 8-quinolinolato structure or a derivative thereof. The derivative of a lithium complex having an 8-quinolinolato structure is preferably a lithium complex having an 8-quinolinolato structure having an alkyl group, and further preferably has a methyl group.

Specific examples of the metal complex include 8-quinolinolato-lithium (abbreviation: Liq) and 8-hydroxyquinolinato-sodium (abbreviation: Naq). In particular, a complex of a monovalent metal ion, especially a complex of lithium is preferable, and Liq is further preferable. Note that in the case where the 8-hydroxyquinolinato structure is included, a methyl-substituted product (e.g., a 2-methyl-substituted product, a 5-methyl-substituted product, or a 6-methyl-substituted product) thereof is also preferably used, for example. In particular, the use of an alkali metal complex having an 8-quinolinolato structure having an alkyl group at the 6 position results in lowering the driving voltage of a light-emitting device.

The electron mobility of the electron-transport layer 114 in the case where the square root of the electric field strength [V/cm] is 600 is preferably higher than or equal to 1×10⁻⁷ cm²/Vs and lower than or equal to 5×10⁻⁵ cm²/Vs. The amount of electrons injected into the light-emitting layer can be controlled by the reduction in the electron-transport property of the electron-transport layer 114, whereby the light-emitting layer can be prevented from having excess electrons. It is particularly preferable to employ this structure when the hole-injection layer is formed using a composite material that includes a material having a hole-transport property with a relatively deep HOMO level higher than or equal to −5.7 eV and lower than or equal to −5.4 eV, in which case a long lifetime can be achieved. In this case, the material having an electron-transport property preferably has a HOMO level higher than or equal to −6.0 eV.

A layer containing an alkali metal, an alkaline earth metal, a compound thereof, or a complex thereof such as lithium fluoride (LiF), cesium fluoride (CsF), calcium fluoride (CaF₂), 8-quinolinolato-lithium (abbreviation: Liq), or ytterbium (Yb) may be provided as the electron-injection layer 115 between the electron-transport layer 114 and the second electrode 102. An electride or a layer that is formed using a substance having an electron-transport property and that contains an alkali metal, an alkaline earth metal, or a compound thereof may be used as the electron-injection layer 115. Examples of the electride include a substance in which electrons are added at high concentration to calcium oxide-aluminum oxide.

Note that as the electron-injection layer 115, it is possible to use a layer containing a substance that has an electron-transport property (preferably an organic compound having a bipyridine skeleton) and includes a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device having higher external quantum efficiency can be provided.

The second electrode 102 is preferably a cathode. As a substance of the cathode, any of metals, alloys, and electrically conductive compounds with a low work function (specifically, lower than or equal to 3.8 eV), mixtures thereof, and the like can be used. Specific examples of such a cathode material include elements belonging to Group 1 or 2 of the periodic table, such as alkali metals (e.g., lithium (Li) and cesium (Cs)), magnesium (Mg), calcium (Ca), and strontium (Sr), alloys containing these elements (e.g., MgAg and AlLi), rare earth metals such as europium (Eu) and ytterbium (Yb), and alloys containing these rare earth metals. However, when the electron-injection layer is provided between the second electrode 102 and the electron-transport layer, a variety of conductive materials such as Al, Ag, ITO, and indium oxide-tin oxide containing silicon or silicon oxide can be used for the cathode regardless of the work function.

When the second electrode 102 is formed using a material that transmits visible light, the light-emitting device can emit light from the second electrode 102 side. When the first electrode 101 is formed on the substrate side, the light-emitting device can be what is called a top-emission light-emitting device.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

Any of a variety of methods can be used for forming the EL layer 103, regardless of whether it is a dry process or a wet process. For example, a vacuum evaporation method, a gravure printing method, an offset printing method, a screen printing method, an ink-jet method, a spin coating method, or the like may be used.

Different deposition methods may be used to form the electrodes or the layers described above.

Although the separate coloring method is used for the light-emitting apparatus described in this embodiment, a white color filter method can also be used for the light-emitting apparatus of one embodiment of the present invention. In that case, the light-emitting devices emit light with the same color and the light-emitting layers 113 contain the same light-emitting substance in some cases; a stacked-layer structure is formed in accordance with the wavelength of light extracted from each subpixel.

### <Tandem Device>

Next, an embodiment of a light-emitting device with a structure in which a plurality of light-emitting units are stacked (also referred to as a stacked device or a tandem device) is described. This light-emitting device includes a plurality of light-emitting layers and a charge-generation layer between a first electrode and a second electrode. The charge-generation layer is positioned between the light-emitting layers. A region interposed between the first electrode and the charge-generation layer, a region interposed between the charge-generation layers, and a region interposed between the charge-generation layer and the second electrode are each referred to as a light-emitting unit.

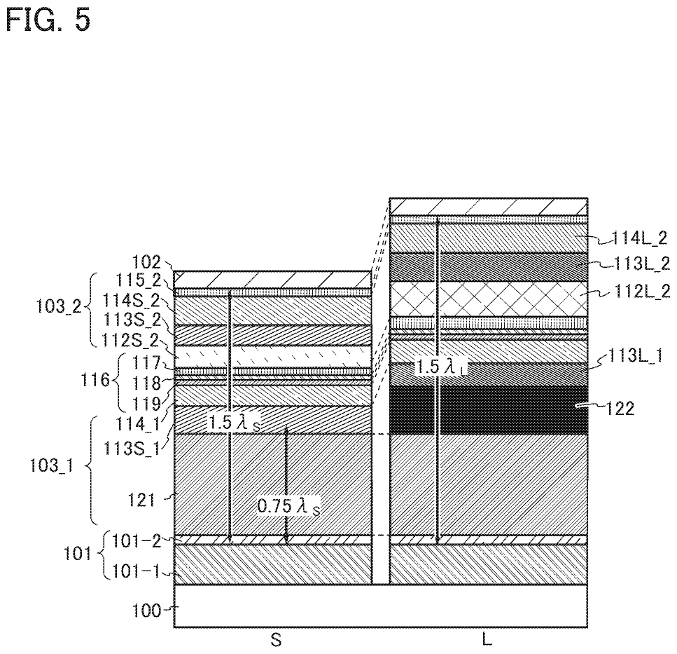

FIG. 5 illustrates an example in which the light-emitting apparatus of one embodiment of the present invention includes a tandem device. The light-emitting device S and the light-emitting device L each include one charge-generation layer 116 and two light-emitting units (a first light-emitting unit 103_1 and a second light-emitting unit 103_2) between the first electrode 101 and the second electrode 102. In the illustrated example, the first electrode 101 has a stacked-layer structure consisting of the reflective electrode 101-1 and the light-transmitting electrode 101-2. Although a light-emitting device including one charge-generation layer 116 and two light-emitting units is described as an example in this embodiment, the light-emitting device may include n charge-generation layers (n is an integer greater than or equal to 2) and n+1 light-emitting units.

The charge-generation layer has a function of injecting holes into a layer in contact with the cathode side and injecting electrons into a layer in contact with the anode side when voltage is applied between the electrodes. That is, in FIG. 5, the charge-generation layer 116 injects electrons into the first light-emitting unit 103_1 and holes into the second light-emitting unit 103_2 when voltage is applied such that the potential of the first electrode 101 becomes higher than the potential of the second electrode 102.

The charge-generation layer 116 includes at least a P-type layer 117. The P-type layer 117 is preferably formed using any of the composite materials given above as the materials that can be used for the hole-injection layer 111. The P-type layer 117 may be formed by stacking a film including the above-described material having an acceptor property and a film including a hole-transport material. When a potential is applied to the P-type layer 117, electrons are injected into an electron-transport layer 114_1 and holes are injected into hole-transport layers 112S_2 and 112L_2; thus, the light-emitting devices operate. Since the P-type layer 117 serves as a hole-injection layer in the light-emitting unit on the cathode side, the hole-injection layer is not necessarily formed in the light-emitting unit on the cathode side (the second light-emitting unit 103_2 in FIG. 5).

Note that the charge-generation layer 116 preferably includes one or both of an electron-relay layer 118 and an electron-injection buffer layer 119 in addition to the P-type layer 117.

The electron-relay layer 118 contains at least the substance having an electron-transport property and has a function of preventing an interaction between the electron-injection buffer layer 119 and the P-type layer 117 and smoothly transferring electrons. The LUMO level of the substance having an electron-transport property contained in the electron-relay layer 118 is preferably between the LUMO level of the acceptor substance in the P-type layer 117 and the LUMO level of a substance contained in a layer of the electron-transport layer 114 that is in contact with the charge-generation layer 116. As a specific value of the energy level, the LUMO level of the substance having an electron-transport property used in the electron-relay layer 118 is preferably higher than or equal to −5.0 eV, further preferably higher than or equal to −5.0 eV and lower than or equal to −3.0 eV. Note that as the substance having an electron-transport property used in the electron-relay layer 118, a phthalocyanine-based material or a metal complex having a metal-oxygen bond and an aromatic ligand is preferably used.

The electron-injection buffer layer 119 can be formed using a substance having a high electron-injection property, e.g., an alkali metal, an alkaline earth metal, a rare earth metal, or a compound thereof (an alkali metal compound (including an oxide such as lithium oxide (Li₂O), a halide, and a carbonate such as lithium carbonate and cesium carbonate), an alkaline earth metal compound (including an oxide, a halide, and a carbonate), or a rare earth metal compound (including an oxide, a halide, and a carbonate)).

In the case where the electron-injection buffer layer 119 contains the substance having an electron-transport property and a donor substance, an organic compound such as tetrathianaphthacene (abbreviation: TTN), nickelocene, or decamethylnickelocene can be used as the donor substance, in addition to an alkali metal, an alkaline earth metal, a rare earth metal, and a compound thereof (e.g., an alkali metal compound (including an oxide such as lithium oxide, a halide, and a carbonate such as lithium carbonate and cesium carbonate), an alkaline earth metal compound (including an oxide, a halide, and a carbonate), or a rare earth metal compound (including an oxide, a halide, and a carbonate)).

As the substance having an electron-transport property that can be used for the electron-injection buffer layer 119, a material similar to the above-described material for the electron-transport layer 114 can be used.

In the case where the charge-generation layer of the tandem device includes the electron-injection buffer layer 119, the electron-injection buffer layer 119 functions as the electron-injection layer in the light-emitting unit on the anode side; thus, an electron-injection layer is not necessarily formed in the light-emitting unit on the anode side (the first light-emitting unit 103_1 in FIG. 5).

The light-emitting device S shows an example in which the first light-emitting unit 103_1 includes a light-emitting layer 113S_1 and the electron-transport layer 114_1 in addition to the first layer 121. Since the first light-emitting unit 103_1 is in contact with the electron-injection buffer layer 119 on the cathode side, the electron-injection layer is not necessarily provided but may be provided. In addition, a hole-injection layer may be provided between the first layer 121 and the light-transmitting electrode 101-2. The light-emitting layer 113S_1 contains a light-emitting substance S_1.

The second light-emitting unit 103_2 of the light-emitting device S includes at least a light-emitting layer 113S_2. The light-emitting layer 113S_2 contains a light-emitting substance S_2. FIG. 5 illustrates an example in which the second light-emitting unit 103_2 includes the hole-transport layer 112S_2, an electron-transport layer 114S_2, an electron-injection layer 115_2 and the like in addition to the light-emitting layer 113S_2. Since the second light-emitting unit 103_2 is in contact with the P-type layer 117 on the anode side, the hole-injection layer is not necessarily provided.

The light-emitting device L shows an example in which the first light-emitting unit 103_1 includes a light-emitting layer 113L_1 and the electron-transport layer 114_1 in addition to the first layer 121 and the second layer 122. Since the first light-emitting unit 103_1 is in contact with the electron-injection buffer layer 119 on the cathode side, the electron-injection layer is not necessarily provided but may be provided. In addition, a hole-injection layer may be provided between the light-transmitting electrode 101-2 and the first layer 121 and the second layer 122. The light-emitting layer 113L_1 contains a light-emitting substance L_1.

The second light-emitting unit 103_2 of the light-emitting device L includes at least a light-emitting layer 113L_2. The light-emitting layer 113L_2 contains a light-emitting substance L_2. FIG. 5 illustrates an example in which the second light-emitting unit 103_2 includes a hole-transport layer 112L_2, an electron-transport layer 114L_2, the electron-injection layer 1152, and the like in addition to the light-emitting layer 113L_2. Since the second light-emitting unit 103_2 is in contact with the P-type layer 117 on the anode side, the hole-injection layer is not necessarily provided.

The light-emitting substance S_1 and the light-emitting substance S_2 are preferably the same substance so that current efficiency significantly increases, though they may be different substances. In the case of different substances, light emitted from the light-emitting substance S_1 and light emitted from the light-emitting substance S_2 are synthesized so that the light-emitting device S emits white light, for example.

In the tandem device of one embodiment of the present invention, a light-emitting unit (the first light-emitting unit 103_1) on the side of the electrode including a reflective electrode preferably includes the first layer 121 and the second layer 122. Furthermore, the light-emitting device is formed such that the optical distance from a surface of the reflective electrode 101-1 on the second electrode 102 side to a surface of the second electrode 102 on the first electrode side is approximately 1.5 times (1.5λ₁) of the wavelength λₜ to be amplified, in which case the light-emitting device can have very high emission efficiency. Light with the wavelength λₜ can be effectively amplified as long as the optical distance is greater than or equal to 70% and less than or equal to 110% of 1.5λₜ.

The wavelength λₜ in the light-emitting device S corresponds to the emission peak wavelength λ_{SD} of light emitted from a subpixel including the light-emitting device S, and the wavelength λₜ in the light-emitting device L corresponds to an emission peak wavelength λ_{LD} of light emitted from a subpixel including the light-emitting device L.

In the case where the light-emitting substance S_1 and the light-emitting substance S_2 are the same, the wavelength λₜ in the light-emitting device S corresponds to the emission peak wavelength λ_{S} of the light-emitting substance S_1 and the light-emitting substance S_2. In the case where the light-emitting substance L_1 and the light-emitting substance L_2 are the same, the wavelength λₜ in the light-emitting device L corresponds to the emission peak wavelength XL of the light-emitting substance L.

In the case where the light-emitting substance S_1 and the light-emitting substance S_2 are different light-emitting substances and light obtained by synthesizing the emission spectrum of the light-emitting substance S_1 and the emission spectrum of the light-emitting substance S_2 has a continuous spectrum from 450 nm to 650 nm (in the case where white light is emitted, for example), it is preferable that the light-emitting substance S_1 and the light-emitting substance L_1 be the same light-emitting substance and the light-emitting substance S_2 and the light-emitting substance L_2 be the same substance. In that case, the wavelength λₜ in the light-emitting device S may be regarded as the emission peak wavelength λ_{SD} of light emitted from a subpixel including the light-emitting device S, and the wavelength λₜ in the light-emitting device L may be regarded as the emission peak wavelength λ_{LD} of light emitted from a subpixel including the light-emitting device L. It is preferable that in this case, the light-emitting layer 113S_1 and the light-emitting layer 113L_1 be a continuous layer and the light-emitting layer 113S_2 and the light-emitting layer 113L_2 be a continuous layer, which facilitates the fabrication process. One or all of the light-emitting layers may each include a plurality of layers containing different light-emitting substances. For example, the light-emitting layer 113S_2 may include a stack of a layer G containing a light-emitting substance G exhibiting green light emission and a layer R containing a light-emitting substance R exhibiting red light emission. In that case, the light-emitting substance S_2 is a collective term of the light-emitting substance G and the light-emitting substance R. Such a structure preferably further includes a color filter.

With a plurality of light-emitting units partitioned by a charge-generation layer between a pair of electrodes in such a manner, light emission with high luminance can be obtained while current density is kept low; thus, a long-life device can be achieved. A light-emitting apparatus that can be driven at a low voltage and has low power consumption can be achieved.

This embodiment can be freely combined with the other embodiments.

### Embodiment 2

In this embodiment, structures other than the light-emitting device in the light-emitting apparatus of one embodiment of the present invention will be described.

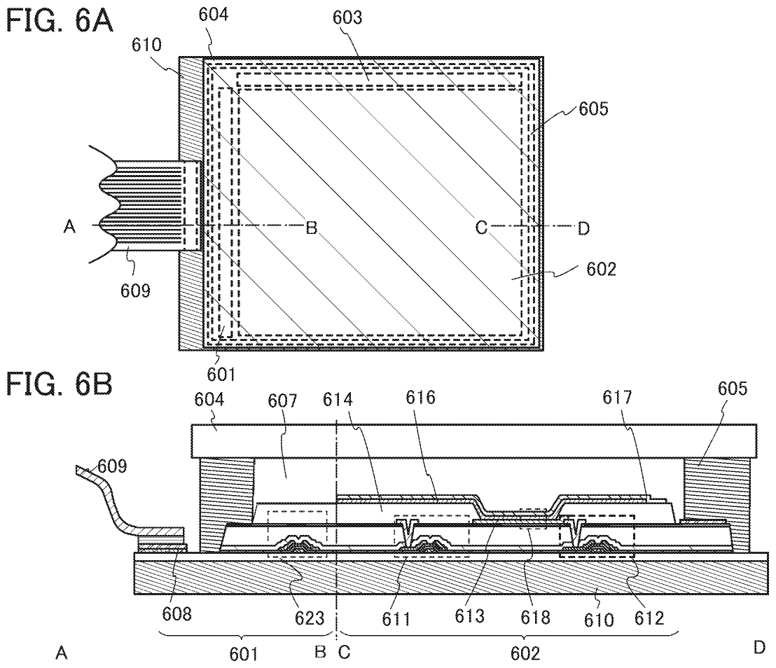

In this embodiment, the light-emitting apparatus of one embodiment of the present invention is described with reference to FIG. 6A and FIG. 6B. Note that FIG. 6A is a top view of the light-emitting apparatus and FIG. 6B is a cross-sectional view taken along the dashed-dotted line A-B and the dashed-dotted line C-D in FIG. 6A. This light-emitting apparatus includes a source line driver circuit 601, a pixel portion 602, and a gate line driver circuit 603, which are to control light emission of a light-emitting device and illustrated with dotted lines. Reference numeral 604 denotes a sealing substrate; 605, a sealing material; and 607, a space surrounded by the sealing material 605.

A lead wiring 608 is a wiring for transmitting signals to be input to the source line driver circuit 601 and the gate line driver circuit 603 and receives a video signal, a clock signal, a start signal, a reset signal, or the like from an FPC (flexible printed circuit) 609 serving as an external input terminal. Although only the FPC is illustrated here, a printed wiring board (PWB) may be attached to the FPC. The light-emitting apparatus in this specification includes, in its category, not only the light-emitting apparatus itself but also the light-emitting apparatus provided with the FPC or the PWB.

Next, a cross-sectional structure is described with reference to FIG. 6B. The driver circuit portions and the pixel portion are formed over an element substrate 610; here, the source line driver circuit 601, which is a driver circuit portion, and one pixel in the pixel portion 602 are illustrated.

The element substrate 610 may be formed using a substrate containing glass, quartz, an organic resin, a metal, an alloy, a semiconductor, or the like or a plastic substrate formed of FRP (Fiber Reinforced Plastics), PVF (polyvinyl fluoride), polyester, an acrylic resin, or the like.

The structure of transistors used in pixels or driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used because deterioration of the transistor characteristics can be inhibited.

Here, an oxide semiconductor is preferably used for semiconductor devices such as transistors provided in the pixels or driver circuits described above and transistors used for touch sensors or the like described later. In particular, an oxide semiconductor having a wider band gap than silicon is preferably used. When an oxide semiconductor having a wider band gap than silicon is used, the off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and having no grain boundary between adjacent crystal parts.

The use of such materials for the semiconductor layer makes it possible to provide a highly reliable transistor in which a change in the electrical characteristics is inhibited.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed in each display region is maintained. As a result, an electronic appliance with extremely low power consumption can be obtained.

For stable characteristics of the transistor and the like, a base film is preferably provided. The base film can be formed with a single layer or stacked layers using an inorganic insulating film such as a silicon oxide film, a silicon nitride film, a silicon oxynitride film, or a silicon nitride oxide film. The base film can be formed by a sputtering method, a CVD (Chemical Vapor Deposition) method (e.g., a plasma CVD method, a thermal CVD method, or an MOCVD (Metal Organic CVD) method), an ALD (Atomic Layer Deposition) method, a coating method, a printing method, or the like. Note that the base film is not necessarily provided when not needed.

Note that an FET 623 is illustrated as a transistor formed in the source line driver circuit 601. The driver circuit may be formed with any of a variety of circuits such as a CMOS circuit, a PMOS circuit, or an NMOS circuit. Although a driver integrated type in which the driver circuit is formed over the substrate is described in this embodiment, the driver circuit is not necessarily formed over the substrate, and the driver circuit can be formed outside, not over the substrate.

The pixel portion 602 includes a plurality of pixels including a switching FET 611, a current controlling FET 612, and a first electrode 613 electrically connected to a drain of the current controlling FET 612. One embodiment of the present invention is not limited to the structure, and a pixel portion in which three or more FETs and a capacitor are combined may be employed.

An insulator 614 is formed to cover an end portion of the first electrode 613. Here, the insulator 614 can be formed using a positive photosensitive acrylic resin film.

In order to improve the coverage with an EL layer or the like which is formed later, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 m to 3 m). As the insulator 614, either a negative photosensitive resin or a positive photosensitive resin can be used.

An EL layer 616 and a second electrode 617 are formed over the first electrode 613. The first electrode 613, the EL layer 616, and the second electrode 617 respectively correspond to the first electrode 101, the EL layer 103, and the second electrode 102 in Embodiment 1.

A light-emitting device is formed with the first electrode 613, the EL layer 616, and the second electrode 617. The light-emitting device is a light-emitting device having the structure described in Embodiment 1.

The sealing substrate 604 is attached to the element substrate 610 with the sealing material 605, so that a light-emitting device 618 is provided in the space 607 surrounded by the element substrate 610, the sealing substrate 604, and the sealing material 605. The space 607 is filled with a filler, and may be filled with an inert gas (such as nitrogen or argon) or the sealing material. It is preferable that the sealing substrate be provided with a depressed portion and a drying agent be provided in the depressed portion, in which case deterioration due to influence of moisture can be inhibited.

An epoxy-based resin or glass frit is preferably used for the sealing material 605. It is desirable that such a material transmit moisture or oxygen as little as possible. As the sealing substrate 604, a glass substrate, a quartz substrate, or a plastic substrate formed of FRP (Fiber Reinforced Plastics), PVF (polyvinyl fluoride), polyester, an acrylic resin, or the like can be used.

Although not illustrated in FIG. 6A and FIG. 6B, a protective film may be provided over the second electrode 617. As the protective film, an organic resin film or an inorganic insulating film may be formed. The protective film may be formed so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material that does not easily transmit an impurity such as water. Thus, diffusion of an impurity such as water from the outside into the inside can be effectively inhibited.

As a material of the protective film, an oxide, a nitride, a fluoride, a sulfide, a ternary compound, a metal, a polymer, or the like can be used. For example, a material containing aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like; a material containing aluminum nitride, hafnium nitride, silicon nitride, tantalum nitride, titanium nitride, niobium nitride, molybdenum nitride, zirconium nitride, gallium nitride, or the like; or a material containing a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like can be used.

The protective film is preferably formed using a deposition method with favorable step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage to a process member in forming the protective film can be reduced.

By an ALD method, a uniform protective film with few defects can be formed even on, for example, a surface with a complex uneven shape or upper, side, and lower surfaces of a touch panel.

As described above, the light-emitting apparatus of one embodiment of the present invention can be obtained.

In the light-emitting apparatus in this embodiment, light emitted from a light-emitting substance is reflected by the interface between layers with different refractive indices, which allows a larger amount of light to be reflected than in the case where light is reflected only by a reflective electrode, and improves external quantum efficiency. At the same time, the influence of surface plasmon in the reflective electrode can be decreased, which reduces energy loss to extract light efficiently. Furthermore, the subpixels include a common layer and each have a stacked-layer structure with a thickness adjusted in accordance with light emitted from the subpixel; as a result, the emission efficiency of all emission colors can be improved easily, promptly, and inexpensively.

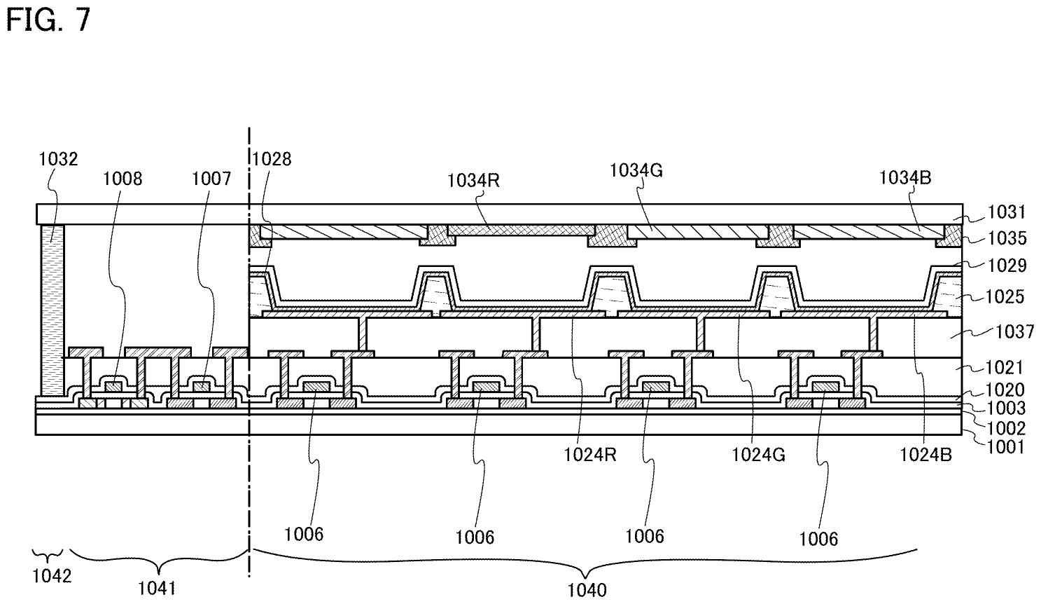

FIG. 7 illustrates an example of a light-emitting apparatus that includes coloring layers (color filters) and the like to improve color purity. FIG. 7 illustrates a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, an electrode 1022, first electrodes 1024R, 1024G, and 1024B of light-emitting devices, a partition 1025, an EL layer 1028, a second electrode 1029 of the light-emitting devices, a sealing substrate 1031, a sealing material 1032, a third interlayer insulating film 1037, and the like.

In the case of a top emission structure as illustrated in FIG. 7, sealing can be performed with the sealing substrate 1031 on which the coloring layers (a red coloring layer 1034R, a green coloring layer 1034G, and a blue coloring layer 1034B) are provided. The sealing substrate 1031 may be provided with a black matrix 1035 which is positioned between pixels. The coloring layers (the red coloring layer 1034R, the green coloring layer 1034G, and the blue coloring layer 1034B) or the black matrix may be covered with an overcoat layer. Note that a light-transmitting substrate is used as the sealing substrate 1031.

The first electrodes 1024R, 1024G, and 1024B of the light-emitting devices each include a reflective electrode here. The first electrodes each preferably include an anode. The EL layer 1028 is formed to have a structure similar to the structure of the EL layer 103 described in Embodiment 1.

In the light-emitting apparatus having a top emission structure, a microcavity structure can be suitably employed. A light-emitting device with a microcavity structure is formed with the use of an electrode including a reflective electrode as one electrode and a transflective electrode as the other electrode. At least an EL layer is provided between the reflective electrode and the transflective electrode, and the EL layer includes at least a light-emitting layer serving as a light-emitting region.

In the light-emitting device, by changing the thickness of the light-transmitting conductive film, the composite material, the carrier-transport material, or the like, the optical distance between the reflective electrode and the transflective electrode can be changed. Thus, light with a wavelength that is resonated between the reflective electrode and the transflective electrode can be intensified while light with a wavelength that is not resonated therebetween can be attenuated.

With the microcavity structure, emission intensity with a specific wavelength in the front direction can be increased, whereby power consumption can be reduced. Note that in the case of a light-emitting apparatus that displays videos with subpixels of four colors of red, yellow, green, and blue, the light-emitting apparatus can have favorable characteristics because the luminance can be increased owing to yellow light emission and each subpixel can employ a microcavity structure suitable for wavelengths of the corresponding color.

In the light-emitting apparatus of one embodiment of the present invention, light emitted from the light-emitting substance is reflected by the interface between layers with different refractive indices, so that a larger amount of light can be reflected than in the case where light is reflected only by a reflective electrode, and external quantum efficiency can be improved. At the same time, the influence of surface plasmon in the reflective electrode can be decreased, which reduces energy loss to extract light efficiently.

In the light-emitting apparatus of one embodiment of the present invention having the above structure, the light-emitting devices include a common low refractive index layer and each have a stacked-layer structure with a thickness adjusted in accordance with light emitted from its subpixel; as a result, the emission efficiency of all emission colors can be improved easily, promptly, and inexpensively.

This embodiment can be freely combined with the other embodiments.

### Embodiment 3

In this embodiment, examples of electronic appliances each including the light-emitting apparatus of one embodiment of the present invention will be described. The light-emitting apparatus of one embodiment of the present invention is a light-emitting device with high emission efficiency and low power consumption. As a result, the electronic appliances described in this embodiment can each include a light-emitting portion with low power consumption.

Examples of the electronic appliance including the above light-emitting device include television devices (also referred to as TV or television receivers), monitors for computers and the like, digital cameras, digital video cameras, digital photo frames, cellular phones (also referred to as mobile phones or mobile phone devices), portable game machines, portable information terminals, audio playback devices, and large game machines such as pachinko machines. Specific examples of these electronic appliances are shown below.

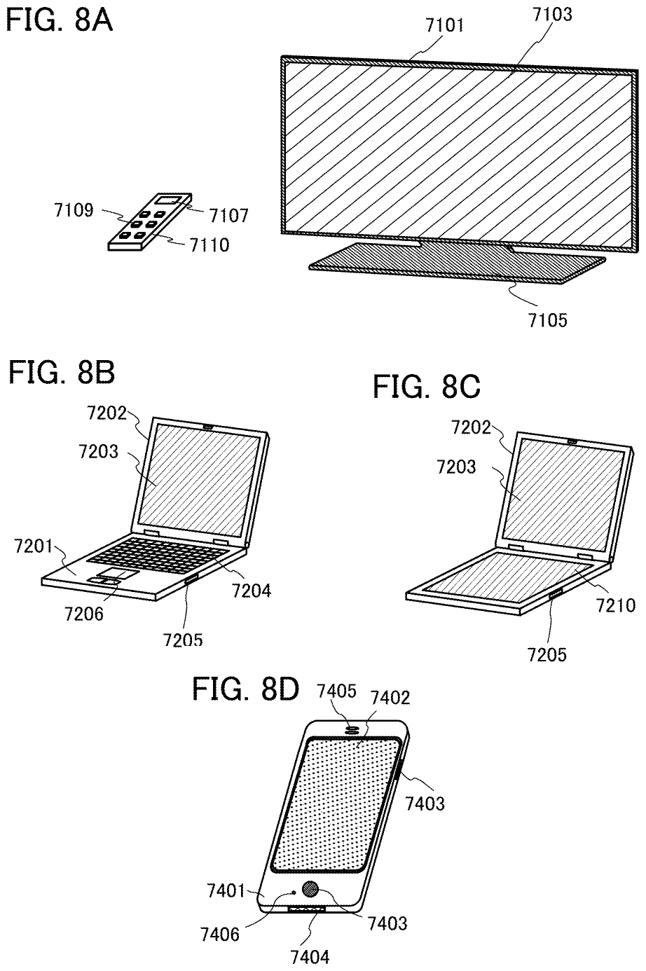

FIG. 8A illustrates an example of a television device. In the television device, a display portion 7103 is incorporated in a housing 7101. Here, the housing 7101 is supported by a stand 7105. Videos can be displayed on the display portion 7103, and the display portion 7103 includes the light-emitting apparatus of one embodiment of the present invention.

The television device can be operated with an operation switch of the housing 7101 or a separate remote controller 7110. With operation keys 7109 of the remote controller 7110, channels and volume can be controlled and videos displayed on the display portion 7103 can be controlled. Furthermore, the remote controller 7110 may be provided with a display portion 7107 for displaying information output from the remote controller 7110. The light-emitting apparatuses of one embodiment of the present invention can be arranged in a matrix also in the display portion 7107.

Note that the television device is provided with a receiver, a modem, and the like. With the use of the receiver, a general television broadcast can be received. Moreover, when the television device is connected to a communication network with or without wires via the modem, one-way (from a sender to a receiver) or two-way (between a sender and a receiver or between receivers) information communication can be performed.

FIG. 8B illustrates a computer, which includes a main body 7201, a housing 7202, a display portion 7203, a keyboard 7204, an external connection port 7205, a pointing device 7206, and the like. Note that this computer is fabricated using the light-emitting apparatus of one embodiment of the present invention in the display portion 7203. The computer illustrated in FIG. 8B may have a structure illustrated in FIG. 8C. A computer illustrated in FIG. 8C is provided with a display portion 7210 instead of the keyboard 7204 and the pointing device 7206. The display portion 7210 is a touch panel, and input operation can be performed by touching display for input on the display portion 7210 with a finger or a dedicated pen. The display portion 7210 can also display images other than the display for input. The display portion 7203 may also be a touch panel. Connecting the two screens with a hinge can prevent troubles; for example, the screens can be prevented from being cracked or broken while the computer is being stored or carried.

FIG. 8D illustrates an example of a portable terminal. A cellular phone is provided with a display portion 7402 incorporated in a housing 7401, operation buttons 7403, an external connection port 7404, a speaker 7405, a microphone 7406, and the like. Note that the cellular phone has the display portion 7402 in which the light-emitting apparatuses of one embodiment of the present invention are arranged in a matrix.

When the display portion 7402 of the portable terminal illustrated in FIG. 8D is touched with a finger or the like, information can be input to the portable terminal. In this case, operations such as making a call and creating an e-mail can be performed by touching the display portion 7402 with a finger or the like.

The display portion 7402 has mainly three screen modes. The first mode is a display mode mainly for displaying images, and the second mode is an input mode mainly for inputting information such as text. The third mode is a display-and-input mode in which the two modes, the display mode and the input mode, are combined.

For example, in the case of making a call or creating an e-mail, a text input mode mainly for inputting text is selected for the display portion 7402 so that text displayed on the screen can be input. In this case, it is preferable to display a keyboard or number buttons on almost the entire screen of the display portion 7402.

When a sensing device including a sensor such as a gyroscope sensor or an acceleration sensor for detecting inclination is provided inside the portable terminal, display on the screen of the display portion 7402 can be automatically changed by determining the orientation of the portable terminal (whether the portable terminal is placed horizontally or vertically).

The screen modes are switched by touching the display portion 7402 or operating the operation buttons 7403 of the housing 7401. Alternatively, the screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal sensed by an optical sensor in the display portion 7402 is sensed, the screen mode may be controlled so as to be switched from the input mode to the display mode.

The display portion 7402 may also function as an image sensor. For example, an image of a palm print, a fingerprint, or the like is taken when the display portion 7402 is touched with the palm or the finger, whereby personal authentication can be performed. Furthermore, by providing a backlight or a sensing light source which emits near-infrared light in the display portion, an image of a finger vein, a palm vein, or the like can be taken.

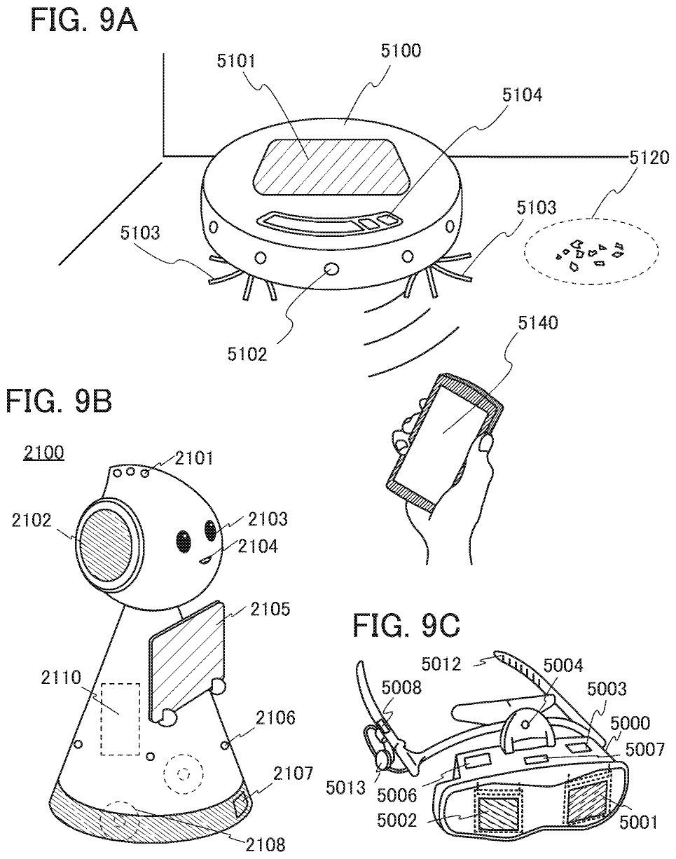

FIG. 9A is a schematic diagram illustrating an example of a cleaning robot.

A cleaning robot 5100 includes a display 5101 on its top surface, a plurality of cameras 5102 on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a wireless communication means.

The cleaning robot 5100 is self-propelled, detects dust 5120, and vacuums the dust through the inlet provided on the bottom surface.

The cleaning robot 5100 can determine whether there is an obstacle such as a wall, furniture, or a step by analyzing images taken by the cameras 5102. When the cleaning robot 5100 detects an object that is likely to be caught in the brush 5103, such as a wire, by image analysis, the rotation of the brush 5103 can be stopped.

The display 5101 can display the remaining capacity of a battery, the amount of vacuumed dust, and the like. The display 5101 may display a path on which the cleaning robot 5100 has run. The display 5101 may be a touch panel, and the operation buttons 5104 may be provided on the display 5101.

The cleaning robot 5100 can communicate with a portable electronic appliance 5140 such as a smartphone. Images taken by the cameras 5102 can be displayed on the portable electronic appliance 5140. Accordingly, an owner of the cleaning robot 5100 can monitor his/her room even when the owner is not at home. The owner can also check the display on the display 5101 by the portable electronic appliance such as a smartphone.

The light-emitting apparatus of one embodiment of the present invention can be used for the display 5101.

A robot 2100 illustrated in FIG. 9B includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 9C illustrates an example of a goggles-type display. The goggles-type display includes, for example, a housing 5000, a display portion 5001, a speaker 5003, an LED lamp 5004 (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, a second display portion 5002, a support 5012, and an earphone 5013.

The light-emitting apparatus of one embodiment of the present invention can be used for the display portion 5001 and the second display portion 5002.

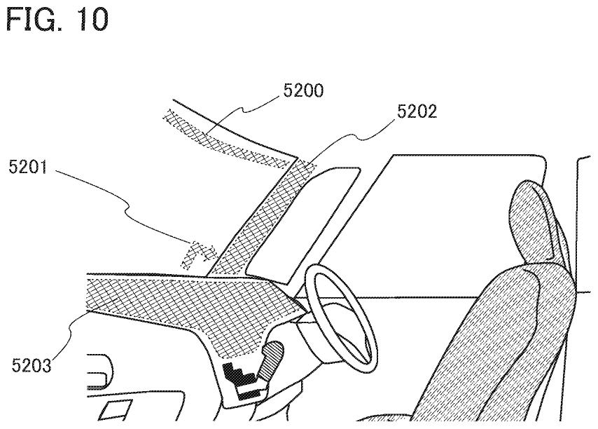

The light-emitting apparatus of one embodiment of the present invention can also be used for an automobile windshield or an automobile dashboard. FIG. 10 illustrates a mode in which the light-emitting apparatus of one embodiment of the present invention is used for an automobile windshield or an automobile dashboard. A display region 5200 to a display region 5203 each include the light-emitting apparatus of one embodiment of the present invention.

The display region 5200 and the display region 5201 are light-emitting apparatuses which are provided in the automobile windshield and include the light-emitting apparatus of one embodiment of the present invention. The light-emitting apparatus of one embodiment of the present invention can be formed into what is called a see-through light-emitting apparatus, through which the opposite side can be seen, by including an anode and a cathode formed of light-transmitting electrodes. Such see-through display devices can be provided even in the automobile windshield without hindering the view. In the case where a driving transistor or the like is provided, a transistor having a light-transmitting property, such as an organic transistor including an organic semiconductor material or a transistor including an oxide semiconductor, is preferably used.

The display region 5202 is a light-emitting apparatus which is provided in a pillar portion and includes the light-emitting apparatus of one embodiment of the present invention. The display region 5202 can compensate for the view hindered by the pillar by displaying a video taken by an imaging unit provided in the car body. Similarly, the display region 5203 provided in the dashboard portion can compensate for the view hindered by the car body by displaying a video taken by an imaging unit provided on the outside of the automobile; thus, blind areas can be eliminated to enhance the safety. Videos that compensate for the areas which a driver cannot see enable the driver to ensure safety easily and comfortably.

The display region 5203 can provide a variety of kinds of information such as navigation information, the speed, the number of rotations, and air-condition setting. The content or layout of the display can be changed as appropriate according to the user's preference. Note that such information can also be displayed on the display region 5200 to the display region 5202. The display region 5200 to the display region 5203 can also be used as lighting devices.

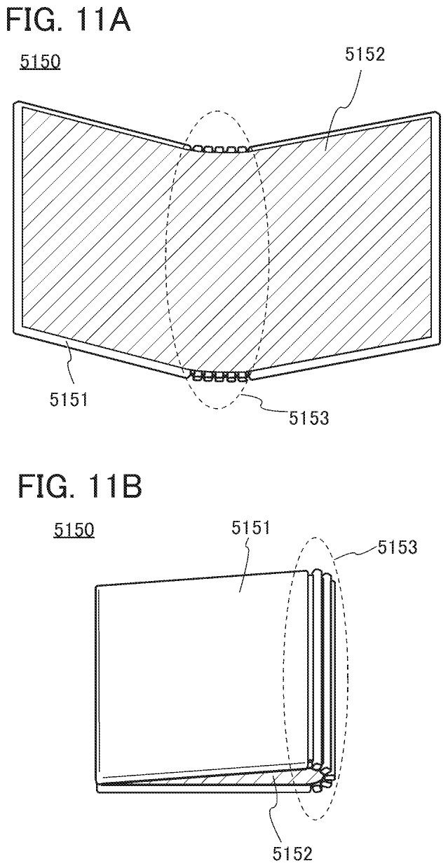

FIG. 11A and FIG. 11B illustrate a foldable portable information terminal 5150. The foldable portable information terminal 5150 includes a housing 5151, a display region 5152, and a bend portion 5153. FIG. 11A illustrates the portable information terminal 5150 that is opened. FIG. 11B illustrates the portable information terminal that is folded. Despite its large display region 5152, the portable information terminal 5150 is compact in size and has excellent portability when folded.

The display region 5152 can be folded in half with the bend portion 5153. The bend portion 5153 includes a flexible member and a plurality of supporting members. When the display region is folded, the flexible member expands. The bend portion 5153 is folded with a curvature radius greater than or equal to 2 mm, preferably greater than or equal to 3 mm.

Note that the display region 5152 may be a touch panel (an input/output device) including a touch sensor (an input device). The light-emitting apparatus of one embodiment of the present invention can be used for the display region 5152.

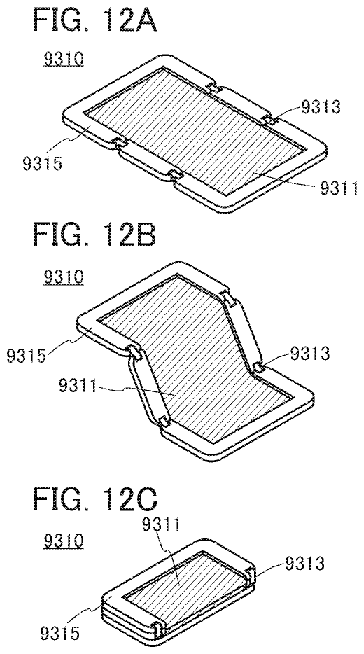

FIG. 12A to FIG. 12C illustrate a foldable portable information terminal 9310. FIG. 12A illustrates the portable information terminal 9310 that is opened. FIG. 12B illustrates the portable information terminal 9310 on the way from either the opened state or the folded state to the other state. FIG. 12C illustrates the portable information terminal 9310 that is folded. The portable information terminal 9310 is highly portable when folded. The portable information terminal 9310 is highly browsable when opened because of a seamless large display region.

A display panel 9311 is supported by three housings 9315 joined together by hinges 9313. Note that the display panel 9311 may be a touch panel (an input/output device) including a touch sensor (an input device). By bending the display panel 9311 at the hinges 9313 between two housings 9315, the portable information terminal 9310 can be reversibly changed in shape from the opened state to the folded state. The light-emitting apparatus of one embodiment of the present invention can be used for the display panel 9311.

Note that the structure described in this embodiment can be combined with any of the structures described in Embodiment 1 and Embodiment 2 as appropriate.

As described above, the application range of the light-emitting apparatus described in Embodiment 1 and Embodiment 2 is so wide that this light-emitting apparatus can be used in electronic appliances in a variety of fields. By using the light-emitting apparatus described in Embodiment 1 and Embodiment 2, an electronic appliance with low power consumption can be obtained.

### Example

This example shows the verification results by calculation of an efficiency improvement effect of a light-emitting device used in the light-emitting apparatus of one embodiment of the present invention. A light-emitting apparatus assumed in this example includes a blue-light-emitting device (a light-emitting device B) having an first layer and a green-light-emitting device (a light-emitting device G) having the first layer as a common layer. The light-emitting devices were verified.

Calculation in this example was performed on the assumption that the light-emitting device B has the structure shown in Table 1 below.

TABLE 1
Light-emitting device B

| | | Film | |
|---|---|---|---|
| | | thickness | |
| | | (nm) | Material |
| Cap layer | | 70.0 | DBT3P-II |
| Second electrode | Cathode | 15.0 | Ag:Mg |
| Electron-transport | 2 | * | NBPhen |
| layer | 1 | 10.0 | 2mDBTBPDBq-II |
| Light-emitting layer | | 25.0 | αN-βNP |
| | | | Anth:dopant |
| Electron-blocking layer | | 10.0 | DBfBB1TP |
| First layer | | * | PCBBiF |
| First electrode | Transparent electrode | 10 | ITSO |
| | (anode) | | |
| | Reflective electrode | 100 | APC |

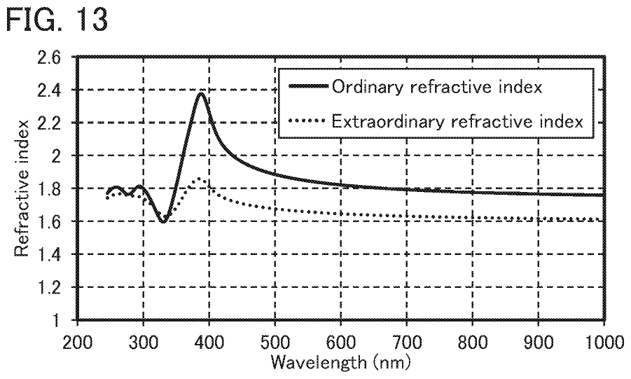

Calculation was performed on the assumption that a high refractive index material, N-(1,1′-biphenyl-4-yl)-N-[4-(9-phenyl-9H-carbazol-3-yl)phenyl]-9,9-dimethyl-9H-fluoren-2-amine (abbreviation: PCBBiF), was used for the first layer 121. FIG. 13 shows the refractive indices in the visible light region of PCBBiF.

APC (an alloy film of silver (Ag), palladium (Pd), and copper (Cu)) is used for a reflective electrode; ITSO (indium tin oxide containing silicon oxide) is used for a light-transmitting electrode (transparent electrode (anode)); N,N-bis[4-(dibenzofuran-4-yl)phenyl]-4-amino-p-terphenyl (abbreviation: DBfBB1TP) is used for an electron-blocking layer; 2-[3-(3′-dibenzothiophen-4-yl)biphenyl]dibenzo[f,h]quinoxaline (abbreviation: 2mDBTBPDBq-II) is used for a first electron-transport layer; 2,9-di(2-naphthyl)-4,7-diphenyl-1,10-phenanthroline (abbreviation: NBPhen) is used for a second electron-transport layer; Ag and Mg are used for the second electrode; and 4,4′,4″-(benzene-1,3,5-triyl)tri(dibenzothiophene) (abbreviation: DBT3P-II) is used for a cap layer.

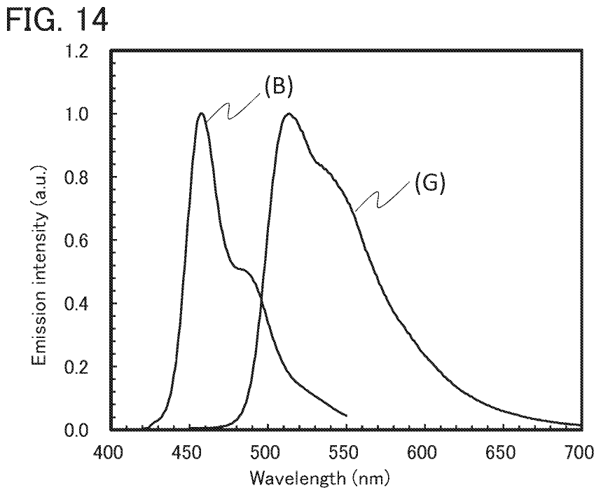

Since a light-emitting layer is generally a mixed layer of a dopant and a host, the calculation in this example was performed using the optical characteristics of a host material, which is larger in amount. The calculation was performed using the value of 9-(1-naphthyl)-10-[4-(2-naphthyl)phenyl]anthracene (abbreviation: (αN-βNPAnth), which is assumed to be used as the host material. Note that light emitted from the light-emitting layer has a spectrum shown as (B) in FIG. 14.

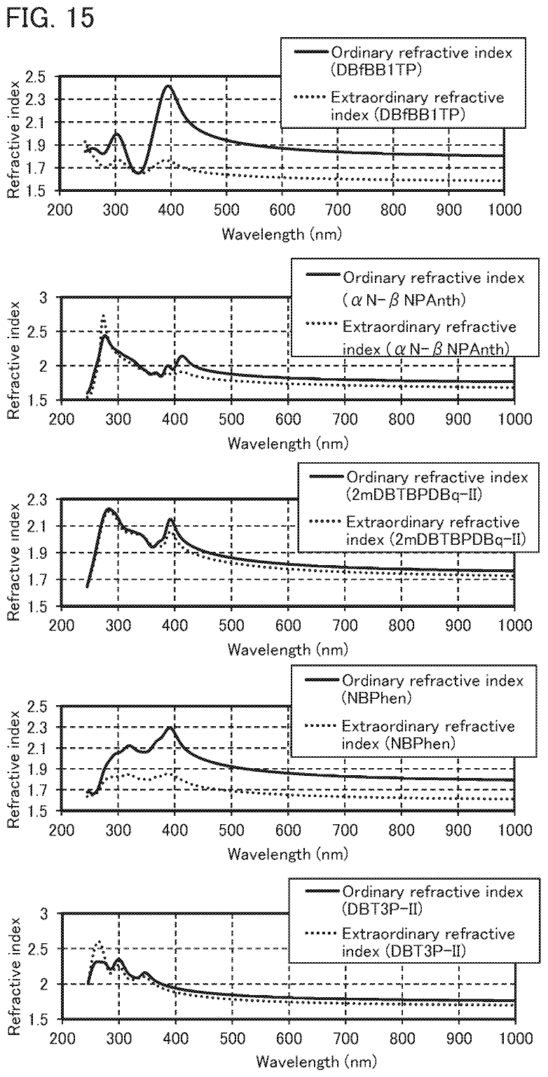

Molecular structures of the organic compounds assumed as the materials of the light-emitting device in this calculation are shown below. FIG. 15 shows the refractive indices in the visible light region of the organic compounds other than PCBBiF. The measurement was performed with a spectroscopic ellipsometer (M-2000U, manufactured by J.A. Woollam Japan Corp.). As a sample used for the measurement, a film is formed to a thickness of approximately 50 nm with the material of each layer over a quartz substrate by a vacuum evaporation method.

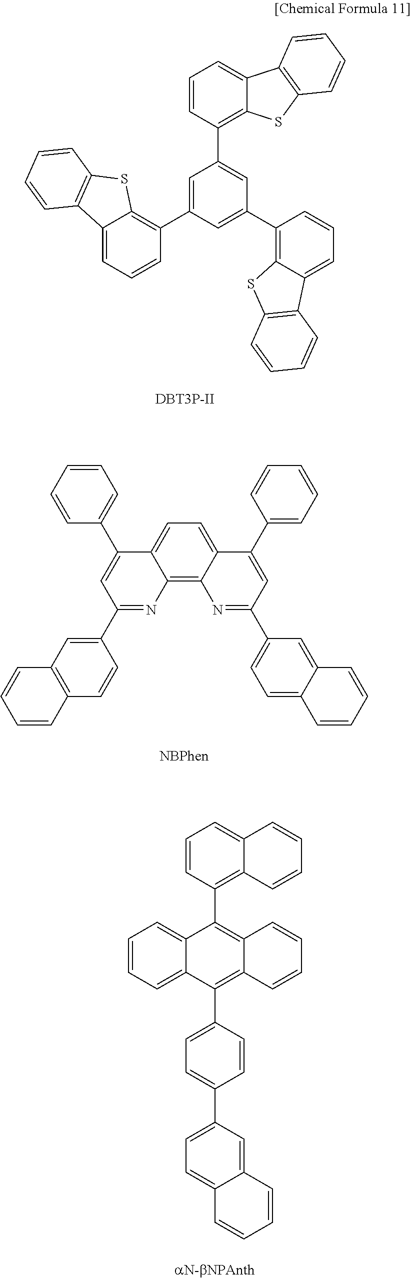

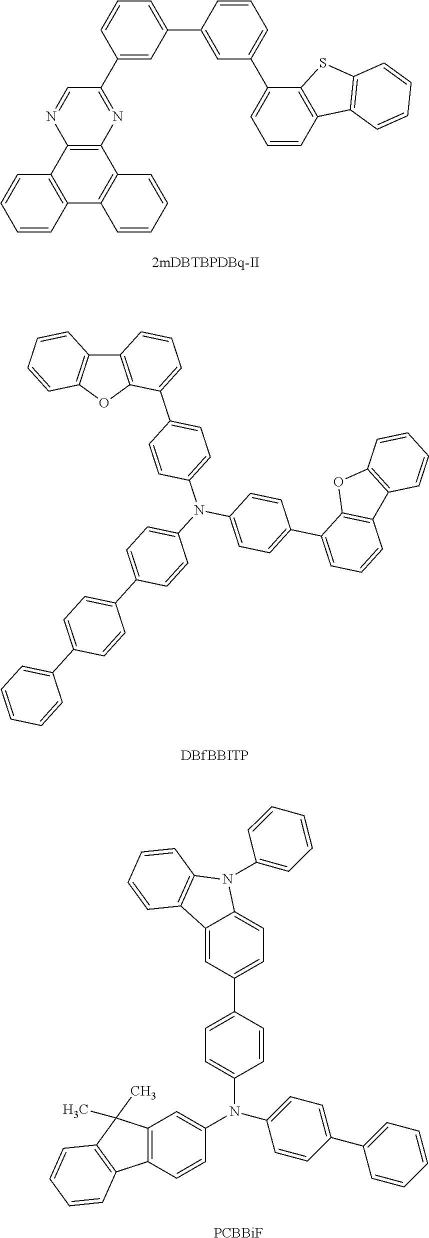

In the light-emitting device B with such a structure, the thicknesses of the first layer 121 and the second electron-transport layer (portions indicated by asterisks (*) in Table 1) were calculated such that the maximum blue index (BI) can be obtained.

The first layer 121 and the second electron-transport layer are assumed to be shared by light-emitting devices with different emission colors (the light-emitting device B and the light-emitting device G in this example). Although the second electron-transport layer is not necessarily shared, it is preferably shared so that the fabrication process can be shortened. Another layer may be set as a common layer.

Note that the blue index (BI) (cd/A/y) is a value obtained by dividing current efficiency (cd/A) by the value of y in the xy chromaticity diagram with the CIE chromaticity coordinates of light, and is one of the indicators of characteristics of blue light emission. As the value of y is smaller, the color purity of blue light emission tends to be higher. With high color purity for blue light emission, a wide range of blue can be expressed even with a small number of luminance components; thus, using blue light emission with high color purity reduces the luminance needed for expressing blue, leading to lower power consumption. Thus, BI that is based on the value of y, which is one of the indicators of color purity of blue, is suitably used as a means for showing efficiency of blue light emission. The light-emitting device with higher BI can be regarded as a blue-light-emitting device having higher efficiency for a display.

In this example, BI is used as an indicator because the color of light with the shortest wavelength in a pixel is blue; in the case where light with the shortest wavelength exhibits any other color, calculation is performed such that any indicator for required performance such as current efficiency is maximized.

The calculation was performed using an organic device simulator (semiconducting emissive thin film optics simulator: setfos; Cybernet Systems Co., Ltd.). It is assumed that a light-emitting region is fixed to the center of a light-emitting layer, no dopant is aligned, and the exciton generation probability and the internal quantum efficiency are each 100%. In addition, quenching due to the Purcell effect is taken into consideration for the calculation.

The following table shows the calculated thicknesses that allow the maximum BI to be obtained in the light-emitting device B having the structure shown in Table 1 above.

TABLE 2

| | | Film thickness |
|---|---|---|
| Layer | | (nm) |
| Electron-transport layer | 2 | 24.9 |

| | |
|---|---|
| First layer | 111.3 |

Next, calculation was performed on a light-emitting device (in this example, a green-light-emitting device, the light-emitting device G) exhibiting an emission color different from that of the above light-emitting device B. The light-emitting device G has a device structure shown in the following table, and includes the first layer 121 and the second electron-transport layer. The first layer 121 has the same structure as the first layer 121 of the light-emitting device B. Note that light emitted from the light-emitting layer of the light-emitting device G has a spectrum shown as (G) in FIG. 14. Note that a light-emitting device G1 corresponds to the light-emitting device L including the second layer 122a (FIG. 1A) and a light-emitting device G2 corresponds to the light-emitting device L including the second layer 122b (FIG. 1).

TABLE 3

| | | |
|---|---|---|
| Film | | |
| thickness | Light-emitting device | Light-emitting device |
| (nm) | G1 | G2 |

| Cap layer | | 70.0 | DBT3P-II |
|---|---|---|---|
| Second electrode | Cathode | 15.0 | Ag:Mg |
| Electron-transport | 2 | 24.9 | NBPhen |
| layer | 1 | 10.0 | 2mDBTBPDBq-II |

| Light-emitting layer | 25.0 | αN-βNP Anth:dopant | |
|---|---|---|---|
| Electron-blocking layer | 10.0 | DBfBB1TP | |
| First layer | — | PCBBiF | dchPAF |
| and | | (First layer 121) | (Second layer 122b) |
| Second layer | | (111.3 nm) | PCBBiF |
| | | dchPAF | (First layer 121) |
| | | (Second layer 122a) | (111.3 nm) |

| | | | |
|---|---|---|---|
| First electrode | Transparent electrode | 10 | ITSO |
| | (anode) | | |
| | Reflective electrode | 100 | APC |

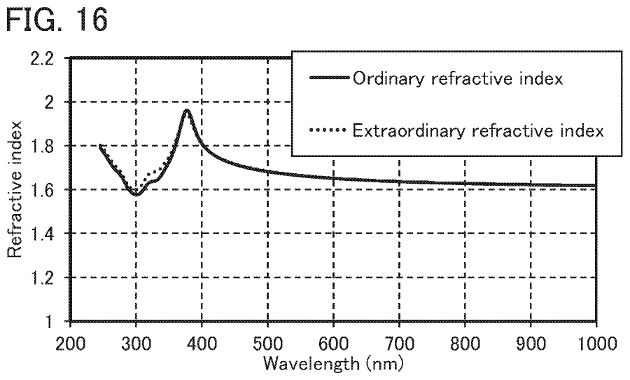

The thickness of the second layer 122 was calculated so that the current efficiency can be maximized in that structure on the assumption that a low refractive index material, N,N-bis(4-cyclohexylphenyl)-9,9-dimethyl-9H-fluoren-2-amine (abbreviation: dchPAF), was used for the second layer 122. FIG. 16 shows the refractive indices in the visible light region of dchPAF. Molecular structures of the organic compounds assumed as the materials of the light-emitting device G in this calculation are shown below.

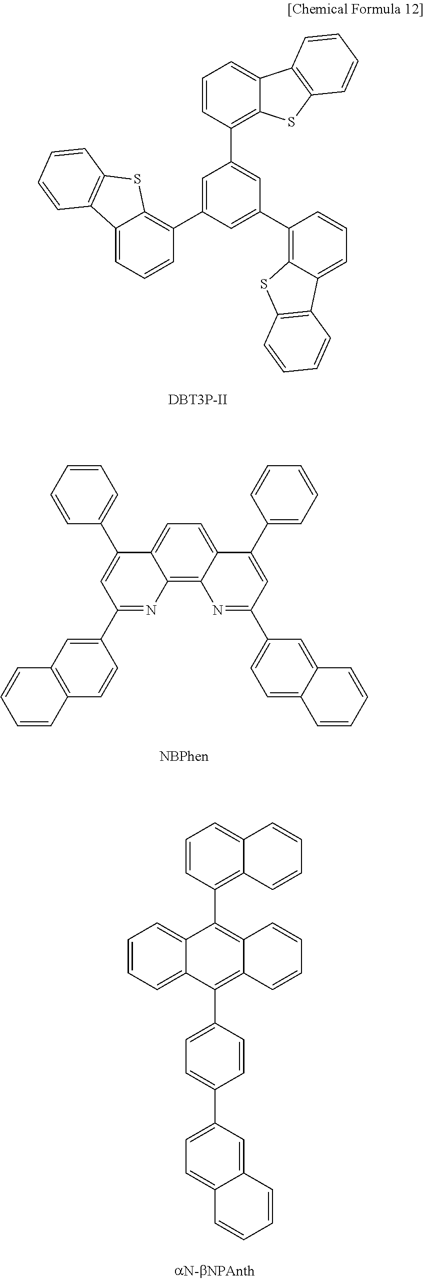

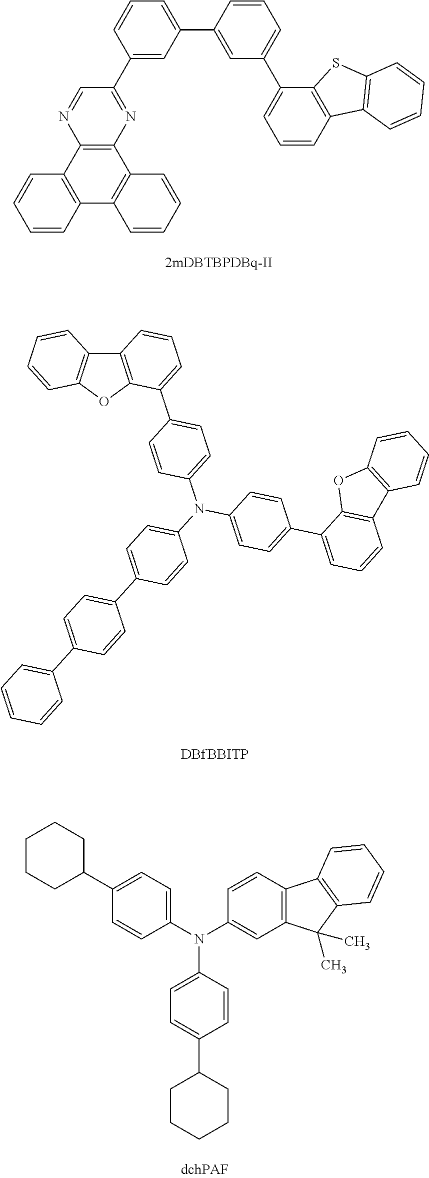 [SMILES: c1cc(-c2cccc(-c3cccc4c3sc3ccccc34)c2)cc(-c2cnc3c4ccccc4c4ccccc4c3n2)c1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; CC1(C)c2ccccc2-c2ccc(N(c3ccc(C4CCCCC4)cc3)c3ccc(C4CCCCC4)cc3)cc21]

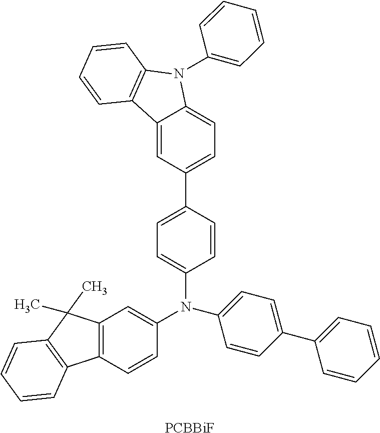

The following table shows the calculation results of the thickness of the second layer 122.

TABLE 4

| | First layer | Second layer |
|---|---|---|
| Light-emitting device G1 | 111.3 nm | 63.34 nm |
| Light-emitting device G2 | | 57.81 nm |

After that, the calculation results on the current efficiency of the light-emitting device G employing the thicknesses shown in the above table are compared with the calculation results on the current efficiency of a comparative light-emitting device G1.

The comparative light-emitting device G1 is a light-emitting device having the same structure as the light-emitting device G except for the materials and thickness of the second layer 122 and thickness of the second electron-transport layer. The second layer 122 of the comparative light-emitting device G1 is formed using PCBBiF and has no refractive index difference. The first layer 121 and the second electron-transport layer have thicknesses obtained such that the above light-emitting device B can have the maximum BI.

That is, like the light-emitting device B and the light-emitting device G, which are assumed to be included in one light-emitting apparatus, the light-emitting device B and the comparative light-emitting device G1 are also assumed to be included in one light-emitting apparatus. The light-emitting device B and the comparative light-emitting device G1 include no low refractive index layer, and thus can be regarded as light-emitting devices with conventional structures.

The element structure of the comparative light-emitting device G1 is shown in the following table.

TABLE 5

| | | Film | Comparative |
|---|---|---|---|
| | | thickness | light-emitting |
| | | (nm) | device G1 |
| Cap layer | | 70.0 | DBT3P-II |
| Second electrode | Cathode | 15.0 | Ag:Mg |
| Electron-transport | 2 | — | NBPhen (24.0 nm) |
| layer | 1 | 10.0 | 2mDBTBPDBq-II |
| Light-emitting layer | | 25.0 | αN-βNP |
| | | | Anth:dopant |
| Electron-blocking layer | | 10.0 | DBfBB1TP |
| First layer and | High | 164.8 | PCBBiF |
| Second layer | | | |
| First electrode | Transparent electrode | 10 | ITSO |
| | (anode) | | |
| | Reflective electrode | 100 | APC |

The following table shows the comparison results of the current efficiency. Note that in the following table, the current efficiency of the light-emitting device G is represented by the proportion of the current efficiency of the light-emitting device G to the current efficiency of the comparative light-emitting device G1.

TABLE 6

| | Proportion of |
|---|---|
| | current efficiency |
| Light-emitting device G1 | 102.9% |
| Light-emitting device G2 | 109.7% |

It was found from the above table that each of the light-emitting device G1 and the light-emitting device G2 has higher current efficiency than the comparative light-emitting device G1. These results shows that in the light-emitting apparatus of one embodiment of the present invention, the current efficiency of the light-emitting device of green light emission can be maintained or improved as well as the first layer 121 is shared by the light-emitting devices of blue light emission and green light emission. This is because light reflected by the interface between the second layer 122 with a low refractive index and the first layer 121 with a high refractive index, light emitted from the light-emitting layer, and light reflected by the electrode are amplified by interference.

It was also found that the light-emitting device G2 has higher efficiency than the light-emitting device G1. This is because the efficiency of light extraction from the light-emitting layer is further improved when the second layer 122 with a low refractive index is close to the light-emitting layer.

In addition, when the stacked-layer structure is shared by the light-emitting devices emitting a plurality of emission colors, a light-emitting apparatus that has high emission efficiency and improved extraction efficiency of the light-emitting devices emitting a plurality of emission colors can be fabricated easily, promptly, and inexpensively.

As described above, in the light-emitting apparatus of one embodiment of the present invention, the layer between the anode and the light-emitting layer, which is adjusted to improve the extraction efficiency of one emission color, is shared by light-emitting devices emitting a plurality of emission colors, a decrease in emission efficiency of the light-emitting devices with the other emission colors is inhibited, and the emission efficiency can be improved. In addition, when the layer between the anode and the light-emitting layer is shared by the light-emitting devices emitting a plurality of emission colors, all the stacked-layer structures do not need to be separately formed for the respective emission colors; hence, a light-emitting apparatus that has high emission efficiency and improved extraction efficiency of the light-emitting devices emitting a plurality of emission colors can be provided easily, promptly, and inexpensively.

### Reference Example 1

In this reference example, light-emitting devices taking the slope of GSP into consideration will be described in detail. Structural formulae of typical organic compounds used in this reference example are shown below.

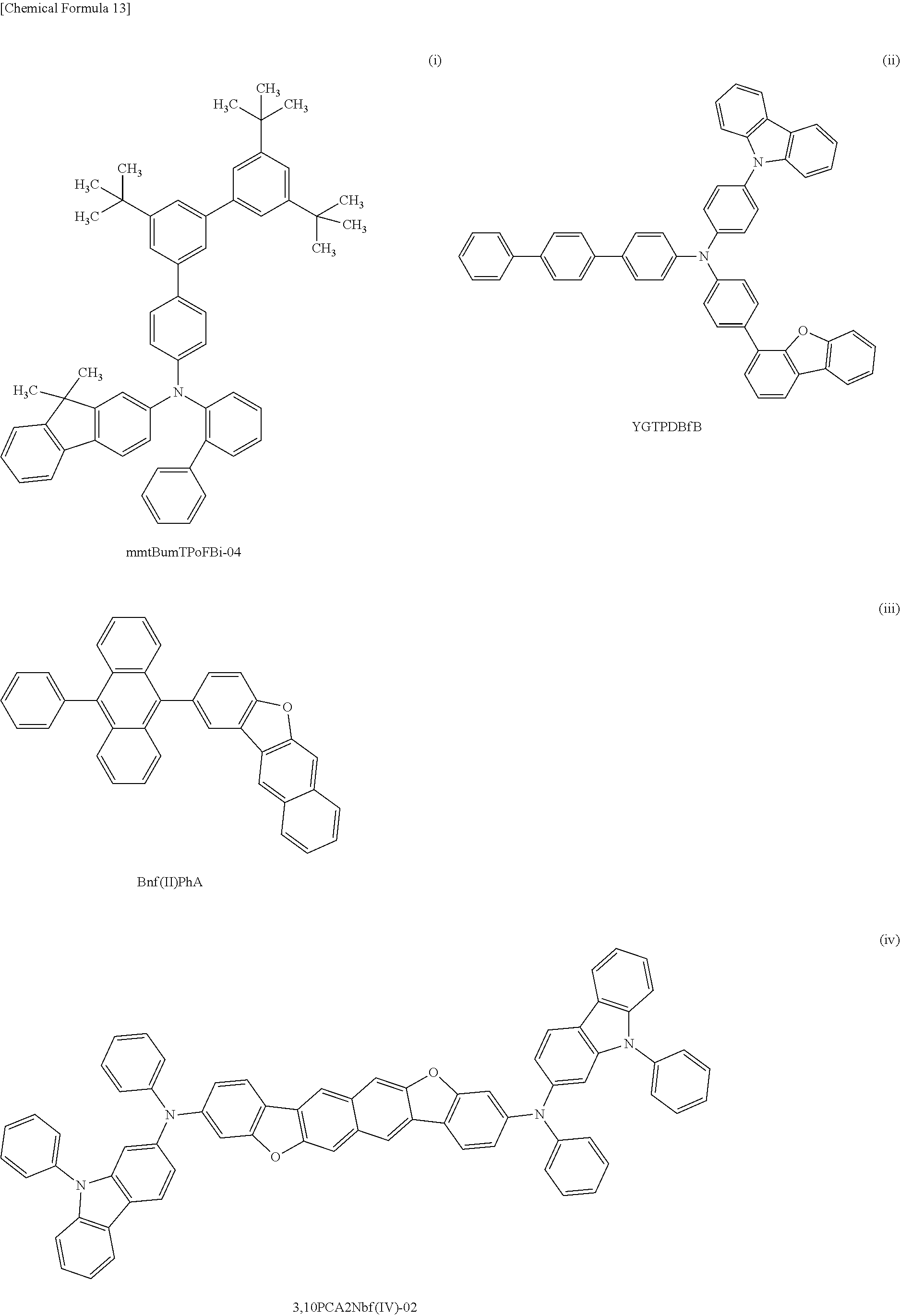 [SMILES: CC(C)(C)c1cc(-c2ccc(N(c3ccc4c(c3)C(C)(C)c3ccccc3-4)c3ccccc3-c3ccccc3)cc2)cc(-c2cc(C(C)(C)C)cc(C(C)(C)C)c2)c1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2c3ccccc3c(-c3ccc4oc5cc6ccccc6cc5c4c3)c3ccccc23)cc1 ; c1ccc(N(c2ccc3c(c2)oc2cc4cc5c(cc4cc23)oc2cc(N(c3ccccc3)c3ccc4c6ccccc6n(-c6ccccc6)c4c3)ccc25)c2ccc3c4ccccc4n(-c4ccccc4)c3c2)cc1]

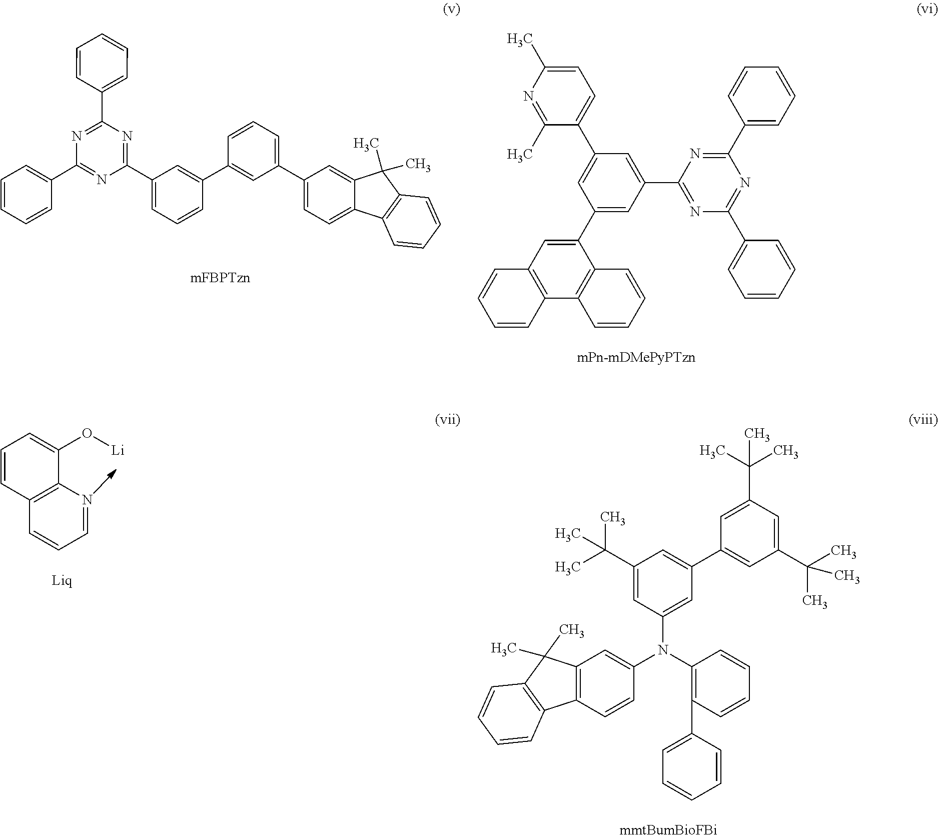

### (Fabrication Method of Light-Emitting Device 1)

First, indium tin oxide containing silicon oxide (ITSO) was deposited over a glass substrate by a sputtering method, whereby the first electrode 101 was formed as an anode. Note that the thickness was 55 nm and the electrode area was set to 2 mm×2 mm.

Next, in pretreatment for forming the light-emitting device over the substrate, a surface of the substrate was washed with water and baked at 200° C. for 1 hour, and then UV ozone treatment was performed for 370 seconds.

After that, the substrate was transferred into a vacuum evaporation apparatus where the pressure was reduced to approximately 10⁻⁴ Pa, vacuum baking was performed at 170° C. for 30 minutes in a heating chamber of the vacuum evaporation apparatus, and then the substrate was cooled down for approximately 30 minutes.

Next, the substrate provided with the first electrode was fixed to a substrate holder provided in the vacuum evaporation apparatus such that the surface on which the first electrode was formed faced downward. Then, by an evaporation method using resistance heating, N-(3″,5′,5″-tri-t-butyl-1,1′:3′,1″-terphenyl-4-yl)-N-(1,1′-biphenyl-2-yl)-9,9-dimethyl-9H-fluoren-2-amine (abbreviation: mmtBumTPoFBi-04) represented by Structural Formula (i) above and a fluorine-containing electron acceptor material with a molecular weight of 672 (OCHD-003) were deposited on the first electrode to a thickness of 10 nm by co-evaporation such that the weight ratio was 1:0.1 (=mmtBumTPoFBi-04: OCHD-003), whereby the hole-injection layer was formed.

Next, mmtBumTPoFBi-04 was deposited by evaporation over the hole-injection layer to a thickness of 100 nm to form a first hole-transport layer, and then N-[4-(9Hcarbazol-9-yl)phenyl]-N-[4-(4-dibenzofuranyl)phenyl]-[1,1′:4′,1″-terphenyl]-4-amine (abbreviation: YGTPDBfB) represented by Structural Formula (ii) above was deposited by evaporation to a thickness of 10 nm, whereby the hole-transport layer was formed.

Over the hole-transport layer, 2-(10-phenyl-9-anthracenyl)-benzo[b]naphtho[2,3-d]furan (abbreviation: Bnf(II)PhA) represented by Structural Formula (iii) above and 3,10-bis[N-(9-phenyl-9H-carbazol-2-yl)-N-phenylamino]naphtho[2,3-b; 6,7-b′]bisbenzofuran (abbreviation: 3,10PCA2Nbf(IV)-02) represented by Structural Formula (iv) above were deposited to a thickness of 25 nm by co-evaporation such that the weight ratio was 1:0.015 (=Bnf(II)PhA:3,10PCA2Nbf(IV)-02), whereby the light-emitting layer was formed.

Next, 2-[3′-(9,9-dimethyl-9H-fluoren-2-yl)-1,1′-biphenyl-3-yl]-4,6-diphenyl-1,3,5-triazine (abbreviation: mFBPTzn) represented by Structural Formula (v) above was deposited by evaporation over the light-emitting layer to a thickness of 10 nm, whereby a hole-blocking layer was formed.

After that, 2-[3-(2,6-dimethyl-3-pyridinyl)-5-(9-phenanthrenyl)phenyl]-4,6-diphenyl-1,3,5-triazine (abbreviation: mPn-mDMePyPTzn) represented by Structural Formula (vi) above and 8-quinolinolato-lithium (abbreviation: Liq) represented by Structural Formula (vii) above were deposited to a thickness of 15 nm by co-evaporation such that the weight ratio was 1:1 (=mPn-mDMePyPTzn:Liq), whereby the electron-transport layer was formed.

After the formation of the electron-transport layer, Liq was deposited by evaporation to a thickness of 1 nm to form the electron-injection layer 115, and lastly, aluminum was deposited by evaporation to a thickness of 200 nm to form the second electrode, whereby the light-emitting device 1 was fabricated.

### (Fabrication Method of Comparative Light-Emitting Device 1)

The comparative light-emitting device 1 was fabricated in the same manner as the light-emitting device 1 except that mmtBumTPoFBi-04 in the light-emitting device 1 was replaced with N-(1,1′-biphenyl-2-yl)-N-[(3,3′,5′-tri-t-butyl)-1,1′-biphenyl-5-yl]-9,9-dimethyl-9H-fluoren-2-amine (abbreviation: mmtBumBioFBi) represented by Structural Formula (viii) above.

The element structures of the light-emitting device 1 and the comparative light-emitting device 1 are listed in the following table.

TABLE 7

| | | Film | Light-emitting | Comparative light- |
|---|---|---|---|---|
| | | thickness | device 1 | emitting device 1 |
| Electron | | 1 nm | Liq | |
| injection layer | | | | |
| Electron | | 15 nm | mPn-mDMePyPTzn: Liq | |
| transport layer | | | (1:1) | |
| Hole | | 10 nm | mFBPTzn | |
| blocking layer | | | | |
| Light-emitting | | 25 nm | Bnf(II)PhA:3,10PCA2Nbf(IV)-02 | |
| layer | | | (1:0.015) | |
| Hole | 2 | 10 nm | YGTPDBfB | |
| transport layer | 1 | 100 nm | mmtBumTPoFBi-04 | mmtBumBioFBi |

| | | | |
|---|---|---|---|
| Hole | 10 nm | mmtBumTPOFBi-04: | mmtBumBioFBi: |
| injection layer | | OCHD-003 | OCHD-003 |
| | | (1:0.1) | (1:0.1) |

The light-emitting device 1 and the comparative light-emitting device 1 were subjected to sealing with a glass substrate (a sealing material was applied to surround the elements, followed by UV treatment and one-hour heat treatment at 80° C. at the time of sealing) in a glove box containing a nitrogen atmosphere so that the light-emitting devices were not exposed to the air. Then, the initial characteristics of these light-emitting devices were measured. Note that the glass substrate over which the light-emitting devices were formed was not subjected to particular treatment for improving light extraction efficiency.

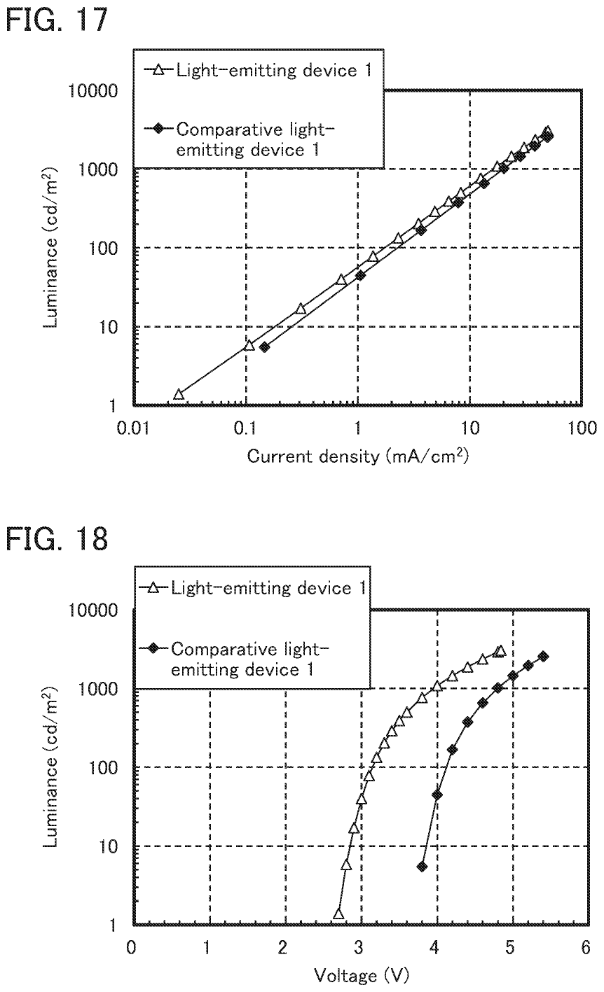

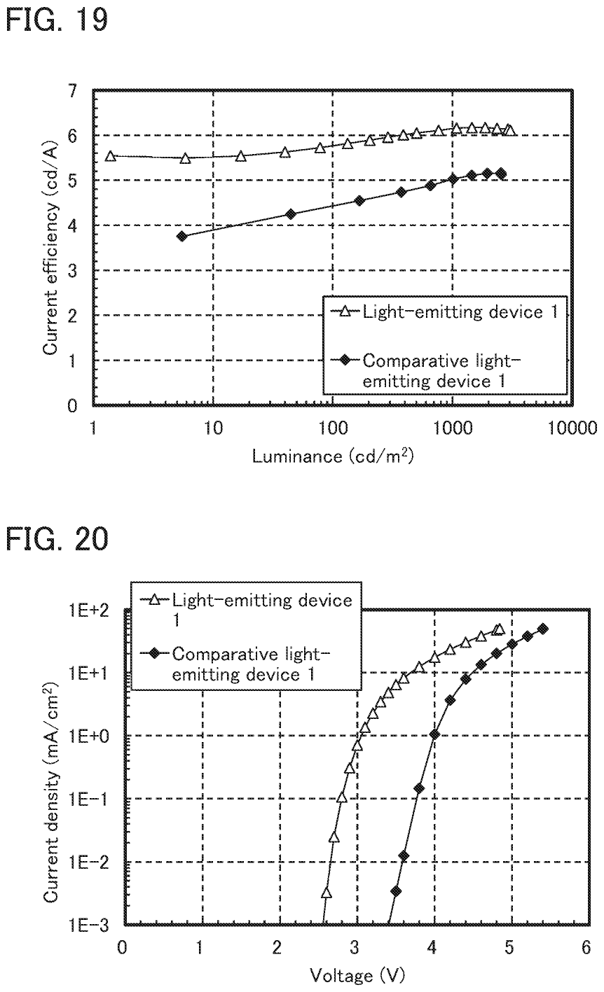

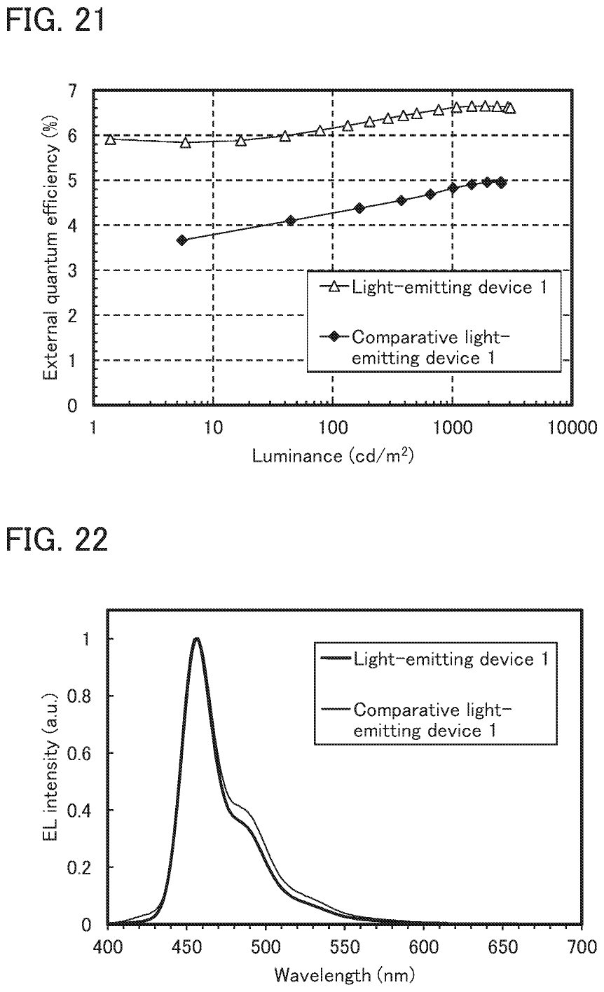

FIG. 17 shows the luminance-current density characteristics of the light-emitting device 1 and the comparative light-emitting device 1. FIG. 18 shows the luminance-voltage characteristics thereof. FIG. 19 shows the current efficiency-luminance characteristics thereof. FIG. 20 shows the current density-voltage characteristics thereof. FIG. 21 shows the external quantum efficiency-luminance characteristics thereof. FIG. 22 shows the emission spectra thereof. The following table shows the main characteristics of the light-emitting devices at around 1000 cd/m². Note that the luminance, CIE chromaticity, and emission spectra were measured at normal temperature with a spectroradiometer (SR-UL1R, manufactured by TOPCON TECHNOHOUSE CORPORATION). The external quantum efficiency was calculated from the measured luminance and emission spectra, on the assumption that the light-emitting devices have Lambertian light-distribution characteristics.

TABLE 8

| | | | Current | | | Current | External |
|---|---|---|---|---|---|---|---|
| | Voltage | Current | density | Chromaticity | Chromaticity | efficiency | quantum |
| | (V) | (mA) | (mA/cm²) | x | y | (cd/A) | efficiency(%) |
| Light-emitting device 1 | 4.0 | 0.70 | 17.6 | 0.14 | 0.10 | 6.2 | 7 |
| Comparative light- | 4.8 | 0.81 | 20.2 | 0.14 | 0.12 | 5.0 | 5 |
| emitting device 1 | | | | | | | |

FIG. 17 to FIG. 22 and the above table show that the light-emitting device 1 has excellent characteristics with lower driving voltage and higher emission efficiency than the comparative light-emitting device 1.

Here, the results of GSP (mV/nm) of the evaporated films of the hole-transport organic compounds used for the hole-transport layers in the light-emitting devices are summarized in the following table. The following table also shows a value (ΔGSP) obtained by subtracting GSP (GSP2) of the hole-transport organic compound (HTM2) used for the hole-transport layer formed later (a second hole-transport layer) from GSP (GSP1) of the hole-transport organic compound (HTM1) used for the hole-transport layer formed first (the first hole-transport layer).

TABLE 9

| | | Comparative light-emitting |
|---|---|---|
| | Light-emitting device 1 | device 1 |
| HTM2 | YGTPDBfB | |
| GSP2 | 8.7 | |
| (mV/nm) | | |
| HTM1 | mmtBumTPOFBi-04 | mmtBumBioFBi |
| GSP1 | 16.7 | 40.6 |
| mV/nm) | | |
| DGPS | 8 | 31.9 |
| (mV/nm) | | |

As shown above, the comparative light-emitting device 1 has large ΔGSP, which implies that a poor property of hole injection from the first hole-transport layer to the second hole-transport layer increases driving voltage. By contrast, it is found that the light-emitting device 1 with small ΔGSP has excellent characteristics with low driving voltage.

### REFERENCE NUMERALS

100: insulating layer, 101: first electrode, 101-1: reflective electrode, 101-2: light-transmitting electrode (anode), 102: second electrode, 103: EL layer, 103_1: first light-emitting unit, 103_2: second light-emitting unit, 111: hole-injection layer, 112L_2: hole-transport layer, 112S_2: hole-transport layer, 113: light-emitting layer, 113L: light-emitting layer, 113S: light-emitting layer, 113S_1: light-emitting layer, 113S_2: light-emitting layer, 113L_1: light-emitting layer, 113L_2: light-emitting layer, 113R: light-emitting layer, 113G: light-emitting layer, 113B: light-emitting layer, 114: electron-transport layer, 114R: electron-transport layer, 114G: electron-transport layer, 114B: electron-transport layer, 114L_2: electron-transport layer, 114_1: electron-transport layer, 114S_2: electron-transport layer, 115: electron-injection layer, 115_2: electron-injection layer, 121: first layer, 122: second layer, 122a: second layer, 122b: second layer, 122Ga: second layer, 122Gb: second layer, 122Ra: second layer, 122Rb: second layer, 123: insulating layer, 130 electron-blocking layer, 601: source line driver circuit, 602: pixel portion, 603: gate line driver circuit, 604: sealing substrate, 605: sealing material, 607: space, 608: wiring, 609: FPC (flexible printed circuit), 610: element substrate, 611: switching FET, 612: current controlling FET, 613: first electrode, 614: insulator, 616: EL layer, 617: second electrode, 618: light-emitting device, 1001 substrate, 1002 base insulating film, 1003 gate insulating film, 1006 gate electrode, 1007 gate electrode, 1008 gate electrode, 1020 first interlayer insulating film, 1021 second interlayer insulating film, 1024R first electrode, 1024G first electrode, 1024B first electrode, 1025 partition, 1028 EL layer, 1029 second electrode, 1031 sealing substrate, 1032 sealing material, 1034R red coloring layer, 1034G green coloring layer, 1034B blue coloring layer, 1035 black matrix, 1037 third interlayer insulating film, 1040 pixel portion, 1041 driver circuit portion, 1042 peripheral portion, 2100: robot, 2110: arithmetic device, 2101: illuminance sensor, 2102: microphone, 2103: upper camera, 2104: speaker, 2105: display, 2106: lower camera, 2107: obstacle sensor, 2108: moving mechanism, 5000: housing, 5001: display portion, 5002: second display portion, 5003: speaker, 5004: LED lamp, 5006: connection terminal, 5007: sensor, 5008: microphone, 5012: support, 5013: earphone, 5100: cleaning robot, 5101: display, 5102: camera, 5103: brush, 5104: operation button, 5150: portable information terminal, 5151: housing, 5152: display region, 5153: bend portion, 5120: dust, 5200: display region, 5201: display region, 5202: display region, 5203: display region, 7101: housing, 7103: display portion, 7105: stand, 7107: display portion, 7109: operation key, 7110: remote controller, 7201: main body, 7202: housing, 7203: display portion, 7204: keyboard, 7205: external connection port, 7206: pointing device, 7210: display portion, 7401: housing, 7402: display portion, 7403: operation button, 7404: external connection port, 7405: speaker, 7406: microphone, 9310: portable information terminal, 9311: display panel, 9313: hinge, 9315: housing

1. A light-emitting apparatus comprising a first light-emitting device and a second light-emitting device,
wherein the first light-emitting device comprises a first electrode, a second electrode, a first light-emitting layer interposed between the first electrode and the second electrode, and a first layer interposed between the first electrode and the first light-emitting layer,
wherein the second light-emitting device comprises a third electrode, a fourth electrode, a second light-emitting layer interposed between the third electrode and the fourth electrode, a second layer interposed between the third electrode and the second light-emitting layer, and a third layer interposed between the third electrode and the second light-emitting layer,
wherein the first light-emitting layer comprises a first light-emitting substance,
wherein the second light-emitting layer comprises a second light-emitting substance,
wherein an emission peak wavelength of the first light-emitting substance is shorter than an emission peak wavelength of the second light-emitting substance,
wherein the first layer and the second layer comprise the same material, and
wherein an ordinary refractive index of the third layer is lower than an ordinary refractive index of the first layer by a value greater than or equal to 0.15, with respect to the emission peak wavelength of the second light-emitting substance.

2. A light-emitting apparatus comprising a first light-emitting device and a second light-emitting device,
wherein the first light-emitting device comprises a first electrode, a second electrode, a first light-emitting layer interposed between the first electrode and the second electrode, and a first layer interposed between the first electrode and the first light-emitting layer,
wherein the second light-emitting device comprises a third electrode, a fourth electrode, a second light-emitting layer interposed between the third electrode and the fourth electrode, a second layer interposed between the third electrode and the second light-emitting layer, and a third layer interposed between the third electrode and the second light-emitting layer,
wherein the first light-emitting layer comprises a first light-emitting substance,
wherein the second light-emitting layer comprises a second light-emitting substance,
wherein an emission peak wavelength of the first light-emitting substance is shorter than an emission peak wavelength of the second light-emitting substance,
wherein the first layer and the second layer are formed using the same material, and
wherein an ordinary refractive index of the third layer is lower than an ordinary refractive index of the first layer by a value greater than or equal to 0.15, with respect to the emission peak wavelength of the second light-emitting substance.

3. A light-emitting apparatus comprising a first light-emitting device and a second light-emitting device,
wherein the first light-emitting device comprises a first electrode, a second electrode, a first light-emitting layer interposed between the first electrode and the second electrode, and a first layer interposed between the first electrode and the first light-emitting layer,
wherein the second light-emitting device comprises a third electrode, a fourth electrode, a second light-emitting layer interposed between the third electrode and the fourth electrode, a second layer interposed between the third electrode and the second light-emitting layer, and a third layer interposed between the third electrode and the second light-emitting layer,
wherein the first light-emitting layer comprises a first light-emitting substance,
wherein the second light-emitting layer comprises a second light-emitting substance,
wherein an emission peak wavelength of the first light-emitting substance is shorter than an emission peak wavelength of the second light-emitting substance,
wherein the first layer and the second layer have structures similar to each other, and
wherein an ordinary refractive index of the third layer is lower than an ordinary refractive index of the first layer by a value greater than or equal to 0.15, with respect to the emission peak wavelength of the second light-emitting substance.

4. The light-emitting apparatus according to claim 1,
wherein the ordinary refractive index of the first layer is higher than or equal to 1.90 with respect to the emission peak wavelength of the first light-emitting substance.

5. The light-emitting apparatus according to claim 1,
wherein the ordinary refractive index of the third layer is lower than or equal to 1.75 with respect to the emission peak wavelength of the second light-emitting substance.

6. The light-emitting apparatus according to claim 1,
wherein the third layer is positioned between the second layer and the second light-emitting layer.

7. The light-emitting apparatus according to claim 1,
wherein the third layer is positioned between the third electrode and the second layer.

8. The light-emitting apparatus according to claim 7,
wherein the third layer comprises a substance having an acceptor property.

9. A display device comprising the light-emitting apparatus according to claim 1.

10. An electronic appliance comprising:
the light-emitting apparatus according to claim 1; and
at least one of a sensor, an operation button, a speaker, and a microphone.
